(19) United States
(12) Patent Application Publication
(10) Pub. No.: US 2026/0085222 A1
(43) Pub. Date: Mar. 26, 2026

(54) POLISHING COMPOSITION

(71) Applicant: Fujimi Incorporated, Kiyosu-shi (JP)

(72) Inventors: Shogo ONISHI, Tualatin, OR (US); Alexandra CARLSON, Tualatin, OR (US)

(73) Assignee: Fujimi Incorporated, Kiyosu-shi (JP)

(21) Appl. No.: 19/336,774

(22) Filed: Sep. 23, 2025

Related U.S. Application Data
(60) Provisional application No. 63/698,658, filed on Sep. 25, 2024.

(51) Int. Cl. C09K 3/14; H01L 21/321

(52) U.S. Cl. CPC C09K 3/1463; H10P 52/403

(57) ABSTRACT

Polishing compositions and methods are provided which enable barrier polishing with improved flatness for patterned substrates comprising copper, tantalum, and TEOS. Provided are polishing compositions comprising: an abrasive with a mean particle size (MPS) of 100 nm to 150 nm; a phosphate surfactant; an electronic conductivity (EC) controller; an organic acid; and a water-soluble polymer, wherein a ratio of a concentration of the abrasive to a concentration of the phosphate surfactant is greater than or equal to 50 and less than or equal to 1040.

### BACKGROUND

### Related Art

The following description of the background of the present technology is provided simply as an aid in understanding the present technology and is not admitted to describe or constitute prior art to the present technology.

One of the principal chemical mechanical polishing (CMP) challenges for semiconductor manufacturing is the selective polishing of materials. Copper (Cu) is widely used as an interconnect material in semiconductor device fabrication, while tantalum (Ta) is widely used as barrier material, and SiO₂ derived from tetraethylorthosilicate (hereinafter “TEOS”) is widely used as a substrate material. Thus, there exists a need for chemical mechanical polishing compositions which minimize loss of Cu interconnects during a barrier polishing steps by offering tunable Cu, Ta, and TEOS removal rates and by achieving good topography correction and flatness. It is against this backdrop that the polishing compositions and methods of the present disclosure were developed.

### SUMMARY

### Solution to Problem

In one aspect, which may be combined with any other aspect or embodiment, the present disclosure relates to a polishing composition, containing: an abrasive, wherein the abrasive has a mean particle size (MPS) of 100 nm to 150 nm; a phosphate surfactant; an electronic conductivity (EC) controller; an organic acid; and a water-soluble polymer, wherein a ratio of a concentration of the abrasive to a concentration of the phosphate surfactant is greater than or equal to 50.

In one aspect, which may be combined with any other aspect or embodiment, the present disclosure relates to a polishing composition, containing: an abrasive, wherein the abrasive has a mean particle size (MPS) of 100 nm to 150 nm; a phosphate surfactant; an electronic conductivity (EC) controller; an corrosion inhibitor; an organic acid; and a water-soluble polymer, wherein a ratio of a concentration of the abrasive to a concentration of the phosphate surfactant is greater than or equal to 50.

In some embodiments, the abrasive contains colloidal silica particles. In some embodiments, the abrasive has a particle size distribution defined by (D90−D10)/D50 of less than or equal to 0.60. In some embodiments, the abrasive contains globular particles. In some embodiments, the abrasive contains particles having an aspect ratio of less than or equal to 1.1.

In some embodiments, the polishing composition has a pH of at less than or equal to 10.5.

In some embodiments, the phosphate surfactant contains a polyoxyethylene alkylphenyl ether phosphate or a polyoxyethylene alkenyl ether phosphate. In some embodiments, the phosphate surfactant contains a polyoxyethylene alkylphenyl ether phosphate having 4 to 16 oxyethylene units. In some embodiments, the phosphate surfactant contains at least one selected from the group consisting of: polyoxyethylene (4) nonylphenylphosphate; polyoxyethylene (7) nonylphenylphosphate; polyoxyethylene (10) nonylphenylphosphate; and polyoxyethylene (10) oleyl ether phosphate.

In some embodiments, the corrosion inhibitor contains an azole compound.

In some embodiments, the corrosion inhibitor contains at least one selected from the group consisting of: benzotriazole (BTA), 1,2,4-triazole, tetrazole, tolytriazole, 4-carboxybenzotriazole, 5-carboxybenzotriazole, mercaptobenzoxazole, 2-mercaptobenzothiazole, 2-mercaptobenzimidazole, and derivatives thereof.

In some embodiments, the organic acid contains at least one selected from citric acid, formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, and lactic acid. In some embodiments, the organic acid contains citric acid.

In some embodiments, the EC controller contains an anion that is the same as an ion present in the organic acid. In some embodiments, the EC controller contains ammonium citrate.

In some embodiments, the water-soluble polymer contains a polysaccharide. In some embodiments, the polysaccharide is pullulan.

In some embodiments, the polishing composition further contains a base selected from KOH, NaOH, or a combination thereof.

In some embodiments, the polishing composition contains an oxidizer. In some embodiments, the oxidizer contains hydrogen peroxide.

In another aspect, which may be combined with any other aspect or embodiment, the present disclosure relates to a method of polishing a substrate surface, wherein the substrate surface contains two or more of Cu, Ta, SiCN, and TEOS, the method containing: contacting the substrate surface with the polishing composition according to any of the embodiments disclosed herein and a polishing pad; and moving the polishing pad against the substrate surface while the polishing composition is in contact with the substrate surface; wherein A2/A3 is 0.85 or greater. In some embodiments, the substrate surface contains Cu and TEOS. In some embodiments, the substrate surface contains Cu, Ta, SiCN, and TEOS.

In some embodiments, the polishing achieves a flatness of the substrate surface of less than or equal to 20, wherein the flatness is defined by (A3−A2)×(0.5×A1). In some embodiments, the flatness is less than or equal to 10.

### BRIEF DESCRIPTION OF THE DRAWINGS

FIG. 1A is a schematic illustration (not to scale) of a Si wafer with a 3000 Å thermal oxide layer patterned with 1-μm trenches (A) having 9-μm inter-trench spacing (B), onto which a 150 Å tantalum (Ta) barrier layer, and 7000 Å copper (Cu) layer have been deposited to simulate interconnects.

FIG. 1B is a schematic illustration of the patterned wafer in FIG. 1A after Cu polishing, leaving the Ta barrier layer across the entire wafer and patterned Cu interconnects in the trenches.

FIG. 1C is a schematic illustration of ideal surface topography after barrier layer polishing the patterned wafer in FIG. 1B. The tops of the Cu and Ta layers are approximately level with the top of the thermal oxide layer on the non-patterned portion of the wafer.

FIG. 1D is a schematic illustration of non-ideal surface topography after barrier layer polishing the patterned wafer in FIG. 1B, where the tops of the Cu and Ta layers are below the top of the thermal oxide layer on the non-patterned portion of the wafer. The amount of erosion is the difference in height between the thermal oxide and Cu or Ta layers.

FIG. 1E is a schematic illustration of non-deal surface topography after barrier layer polishing the patterned wafer in FIG. 1B, where the top of the Ta barrier layer is below the top of the thermal oxide layer on the non-patterned portion of the wafer (erosion), and the Cu layer protrudes above the top of the Ta barrier layer due to non-ideal Ta/Cu removal rate selectivity.

FIG. 1F is a schematic illustration of non-ideal surface topography after barrier layer polishing the patterned wafer in FIG. 1B, where top of the Cu layer (and optionally the top of the Ta layer) is below the top of the thermal oxide layer on the non-patterned and patterned portions of the wafer, due to Cu “dishing.”

FIG. 2 is a schematic illustration showing the parameters for flatness calculation for a TEOS/Ta/Cu patterned wafer.

Reference will now be made in detail to some specific embodiments contemplated by the present disclosure. While various embodiments are described herein, it will be understood that it is not intended to limit the present technology to the described embodiments. On the contrary, it is intended to cover alternatives, modifications, and equivalents as may be included within the spirit and scope of the technology as defined by the appended claims.

The expression “X to Y” used herein means “greater than or equal to X and less than or equal to Y”, meaning to include the numerical values at both ends (X and Y) as the lower and upper limits. If one or more expressions “X to Y” are described, for example, if it is described as “X1 to Y1, or X2 to Y2”, the disclosure of each numerical value as the upper limit, the disclosure of each numerical value as the lower limit, and a combination of these upper and lower limits are all disclosed (that is, these are legal grounds for amendment). Specifically, amendments with greater than or equal to X1, amendments with less than or equal to Y2, amendments with less than or equal to X1, amendments with greater than or equal to Y2, amendments with X1 to X2, amendments with X1 to Y2, etc. must all be considered legal. Note that the description “greater than or equal to X” includes the meaning of “greater than X”, since it means X or greater than X. Similarly, the description “less than or equal to Y” includes the meaning of “less than Y”, since it means Y or less than Y. In addition, unless otherwise specified, operations and measurements of physical properties, etc. are performed in the conditions of room temperature (20 to 25° C.) and relative humidity of 40 to 50% RH. Note that the concentrations described herein may be concentrations at the point of use (POU) or concentrations before dilution to the POU concentrations. The dilution factor may be 2 to 10 times. In addition, it should be understood that all combinations of embodiments and explanations disclosed herein are disclosed in this application. That is, it should be understood that they can be grounds for amendment. Further, when the content or concentration of each ingredient is described, it may be the total amount if two or more types are included.

### DETAILED DESCRIPTION

### Polishing Composition

The present disclosure relates to a polishing composition, containing: an abrasive; a phosphate surfactant; an electronic conductivity (EC) controller; an organic acid; and a water-soluble polymer. In one aspect, which may be combined with any other aspect or embodiment, the present disclosure relates to a polishing composition, containing: an abrasive; a phosphate surfactant; an electronic conductivity (EC) controller; an corrosion inhibitor; an organic acid; and a water-soluble polymer.

### Abrasive

Polishing compositions according to the present disclosure contain abrasive particles (i.e., “abrasive grains”) suitable for polishing a substrate containing Cu, Ta, and one or more dielectric materials (e.g., BD, SiO₂ (e.g., derived from TEOS), etc.). Since the abrasive consists of a plurality of abrasive particles (abrasive grains), the term abrasive particles (abrasive grains) may be used herein to mean the abrasive. In some embodiments, the abrasive particles contain one or more metal oxide particles, e.g., zirconia, hafnia, alumina, titania, silica, ceria, and any combination thereof. In some embodiments, the abrasive particles contain colloidal silica, colloidal zirconia, or combinations thereof. In some embodiments, the abrasive particles contain colloidal silica. In addition, the abrasive particles may be a commercial product, synthetic product, or any combination thereof. In some embodiments, the abrasive particles have a negative surface charge or negative zeta potential, a positive surface charge or positive zeta potential, or are uncharged (i.e., are neutral) at the pH of the polishing composition.

In some embodiments, the abrasive particles are surface-modified by a chemical species covalently attached to the particle surface and having a terminal anionic group. In some embodiments, the abrasive particles contain colloidal particles which are anionically modified, e.g., by immobilization of an organic acid on the colloidal particle surface.

In some embodiments, immobilization of an organic acid on the surface of the abrasive particles (e.g., colloidal silica) in the polishing composition may be carried out by chemically bonding a functional group of the organic acid to the surface of the abrasive particle (e.g., colloidal silica). The immobilization of an organic acid on colloidal silica cannot be achieved by only allowing colloidal silica and an organic acid to merely coexist. The immobilization of an organic acid (e.g., a sulfonic acid), on colloidal silica can be carried out, for example, by a method described in E. Cano-Serrano et al., Sulfonic acid-functionalized silica through quantitative oxidation of thiol groups, Chem. Commun. 246-47 (2003), which is hereby incorporated by reference in its entirety. Specifically, colloidal silica with a sulfonic acid immobilized on its surface can be obtained by coupling a silane coupling agent having a thiol group, such as 3-mercaptopropyl trimethoxysilane (“MIPS”), to colloidal silica, followed by oxidizing the thiol group with hydrogen peroxide to form a surface-immobilized sulfonic acid (e.g., a surface-bound propane sulfonic acid, such as oxidized MPS). Such silica abrasives are non-limiting examples of “sulfonic acid-modified” abrasives. Surface modified colloidal silica in Examples is this sulfonic acid-modified colloidal silica.

The immobilization of a carboxylic acid on colloidal silica can be carried out, for example, by a method described in Y. Kazuo et al., Novel Silane Coupling Agents Containing a Photolabile 2-Nitrobenzyl Ester for Introduction of a Carboxy Group on the Surface of Silica Gel, 3 Chem. Lett. 228-29 (2000), which is hereby incorporated by reference in its entirety. Specifically, colloidal silica in which a carboxylic acid is immobilized on its surface can be obtained by coupling a silane coupling agent including photoreactive 2-nitrobenzyl ester to colloidal silica, followed by photoirradiation. Such silica abrasives are non-limiting examples of “carboxylic acid-modified” abrasives.

These examples of organic acid immobilization on colloidal silica are intended to be exemplary and are not intended to be limiting. Other organic immobilization techniques using different organic acids and different abrasive particle materials (e.g., other than colloidal silica) are intended to be encompassed within the scope of the present disclosure.

In some embodiments, the abrasive particles are unmodified (i.e., have no chemical species, such as an organic compound with a charged headgroup, bound to the surface).

In some embodiments, the abrasive particles have a mean particle size (MPS) of greater than or equal to about 10 nm, greater than or equal to about 15 nm, greater than or equal to about 20 nm, greater than or equal to about 25 nm, greater than or equal to about 30 nm, greater than or equal to about 35 nm, greater than or equal to about 40 nm, greater than or equal to about 45 nm, greater than or equal to about 50 nm, greater than or equal to about 55 nm, greater than or equal to about 60 nm, greater than or equal to about 65 nm, greater than or equal to about 70 nm, greater than or equal to about 75 nm, greater than or equal to about 80 nm, greater than or equal to about 85 nm, greater than or equal to about 90 nm, greater than or equal to about 95 nm, greater than or equal to about 100 nm, greater than or equal to about 110 nm, greater than or equal to about 120 nm, greater than or equal to about 130 nm, greater than or equal to about 140 nm, greater than or equal to about 150 nm, greater than or equal to about 160 nm, greater than or equal to about 170 nm, greater than or equal to about 180 nm, greater than or equal to about 190 nm, greater than or equal to about 200 nm, greater than or equal to about 210 nm, greater than or equal to about 220 nm, greater than or equal to about 230 nm, greater than or equal to about 240 nm, greater than or equal to about 250 nm, greater than or equal to about 260 nm, greater than or equal to about 270 nm, greater than or equal to about 280 nm, greater than or equal to about 290 nm, greater than or equal to about 300 nm, or any range or value including and/or in between any two of these values. Mean particle sizes (MPS) of abrasive particles (abrasive) herein are values calculated using a ZETASIZER® (Malvern Panalytical) as shown in Examples. Here, ranges can be expressed herein as from “about” one particular value and/or to “about” another particular value. When such a range is expressed, another aspect contains from the one particular value and/or to the other particular value. Similarly, when values are expressed as approximations, by using the antecedent “about”, it will be understood that the particular value forms another aspect. Further, it will be understood that one endpoint of each range is important in relation to the other endpoint, and independently from the other endpoint. It will also be understood that there are a large number of values disclosed herein, and that each value is disclosed herein as “about” the particular value in addition to the value itself. For example, if the value “10” is disclosed, then “about 10” is also disclosed. It will also be understood that each structural unit between two particular structural units is also disclosed. For example, if 10 and 15 are disclosed, then 11, 12, 13, and 14 are also disclosed. When used herein, about X (X is a numerical value) can mean that it further includes ±10% or ±5%, and when ±10% is used as an example, it means X×0.9 to X×1.1. In addition, about X may be X itself.

In some embodiments, the abrasive particles have a mean particle size (MPS) of less than or equal to about 300 nm, less than or equal to about 290 nm, less than or equal to about 280 nm, less than or equal to about 270 nm, less than or equal to about 260 nm, less than or equal to about 250 nm, less than or equal to about 240 nm, less than or equal to about 230 nm, less than or equal to about 220 nm, less than or equal to about 210 nm, less than or equal to about 200 nm, less than or equal to about 190 nm, less than or equal to about 180 nm, less than or equal to about 170 nm, less than or equal to about 160 nm, less than or equal to about 150 nm, less than or equal to about 140 nm, less than or equal to about 130 nm, less than or equal to about 120 nm, less than or equal to about 110 nm, less than or equal to about 100 nm, less than or equal to about 95 nm, less than or equal to about 90 nm, less than or equal to about 85 nm, less than or equal to about 80 nm, less than or equal to about 75 nm, less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 35 nm, less than or equal to about 30 nm, less than or equal to about 25 nm, less than or equal to about 20 nm, less than or equal to about 15 nm, less than or equal to about 10 nm, or any range or value including and/or in between any two of these values.

In some embodiments, the abrasive particles have a mean particle size (MPS) of about 10 nm to about 300 nm, about 20 nm to about 250 nm, about 30 nm to about 200 nm, about 50 nm to about 200 nm, about 70 nm to about 180 nm, about 80 nm to about 170 nm, about 90 nm to about 160 nm, about 100 nm to about 150 nm, about 110 nm to about 130 nm, or any range or value including and/or in between any two of these values. In some embodiments, the abrasive particles (abrasive) have a mean particle size (MPS) of about 115 nm to about 125 nm, or any range or value including and/or in between any two of these values.

The terms “D10,” “D50,” and “D90” refer to parameters of a particle size distribution for the abrasive particles (or abrasive grains) disclosed herein. As used herein, the term “D10” refers to the particle size (e.g., diameter) at 10% of the cumulative count from the smallest particle size in the particle size distribution histogram. That is, D10 is the particle size at which 10% of the particles in the particle size distribution have a smaller size and 90% have a larger size. Similarly, as used herein, the term “D50” refers to the particle size (e.g., diameter) at 50% of the cumulative count from the smallest particle size in the particle size distribution histogram. That is, D50 is the particle size at which 50% of the particles in the particle size distribution have a smaller size and 50% have a larger size. Likewise, “D90” refers to the particle size (e.g., diameter) at 90% of the cumulative count from the smallest particle size in the particle size distribution histogram. That is, D90 is the particle size at which 90% of the particles in the particle size distribution have a smaller size and 10% have a larger size. “D10”, “D50”, and “D90” can all be measured by Malvern Panalytical's Zetasizer Nano Light Scattering system.

In some embodiments, the abrasive particles have a narrow size distribution suitable to improve the flatness and topography correction of an object being polished using the polishing composition. In some embodiments, the size distribution is determined according to Equation 1 below:

$$Size Distribution = \frac{( {D}_{90} - {D}_{10} )}{{D}_{50}} , \qquad ( 1 )$$

wherein a smaller value indicates a narrower size distribution.

In some embodiments the size distribution ([D₉₀−D₁₀]/D₅₀) of the abrasive particles is less than or equal to about 2.0, less than or equal to about 1.9, less than or equal to about 1.8, less than or equal to about 1.7, less than or equal to about 1.6, less than or equal to about 1.5, less than or equal to about 1.4, less than or equal to about 1.3, less than or equal to about 1.2, less than or equal to about 1.1, less than or equal to about 1.0, less than or equal to about 0.95, less than or equal to about 0.90, less than or equal to about 0.85, less than or equal to about 0.80, less than or equal to about 0.75, less than or equal to about 0.70, less than or equal to about 0.65, less than or equal to about 0.60, less than or equal to about 0.55, less than or equal to about 0.50, less than or equal to about 0.45, less than or equal to about 0.40, less than or equal to about 0.35, less than or equal to about 0.30, less than or equal to about 0.25, less than or equal to about 0.20, less than or equal to about 0.15, less than or equal to about 0.10, or any range or value including and/or in between any two of these values. In some embodiments, the size distribution ([D₉₀−D₁₀]/D₅₀) of the abrasive particles (abrasive) is less than or equal to 0.66, less than or equal to 0.65, less than or equal to 0.64, less than or equal to 0.63, less than or equal to 0.62, less than or equal to 0.61, less than or equal to 0.59, less than or equal to 0.58, or less than or equal to 0.57, or any range or value including and/or in between any two of these values. In some embodiments, the size distribution ([D₉₀−D₁₀]/D₅₀) of the abrasive particles (abrasive) is greater than or equal to 0.10, greater than or equal to 0.20, greater than or equal to 0.30, greater than or equal to 0.40, greater than or equal to 0.50, greater than or equal to 0.51, greater than or equal to 0.52, greater than or equal to 0.53, greater than or equal to 0.54, or greater than or equal to 0.55, or any range or value including and/or in between any two of these values.

As used herein, the polishing composition may be simply referred to as “composition”.

In some embodiments, the abrasive particles are present in the composition at a concentration by weight, relative to the total weight of the composition, of greater than or equal to about 0.1 wt. %, greater than or equal to about 0.15 wt. %, greater than or equal to about 0.2 wt. %, greater than or equal to about 0.25 wt. %, greater than or equal to about 0.3 wt. %, greater than or equal to about 0.35 wt. %, greater than or equal to about 0.4 wt. %, greater than or equal to about 0.45 wt. %, greater than or equal to about 0.5 wt. %, greater than or equal to about 0.55 wt. %, greater than or equal to about 0.60 wt. %, greater than or equal to about 0.65 wt. %, greater than or equal to about 0.7 wt. %, greater than or equal to about 0.75 wt. %, greater than or equal to about 0.8 wt. %, greater than or equal to about 0.85 wt. %, greater than or equal to about 0.9 wt. %, greater than or equal to about 0.95 wt. %, greater than or equal to about 1.0 wt. %, greater than or equal to about 1.1 wt. %, greater than or equal to about 1.2 wt. %, greater than or equal to about 1.3 wt. %, greater than or equal to about 1.4 wt. %, greater than or equal to about 1.5 wt. %, greater than or equal to about 1.6 wt. %, greater than or equal to about 1.7 wt. %, greater than or equal to about 1.8 wt. %, greater than or equal to about 1.9 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value therein between. In some embodiments, the abrasive particles (abrasive) are present in the composition at a concentration by weight, relative to the total weight of the composition, of greater than or equal to 3.6 wt. %, greater than or equal to 3.7 wt. %, greater than or equal to 3.8 wt. %, greater than or equal to 3.9 wt. %, greater than or equal to 4.1 wt. %, greater than or equal to 4.2 wt. %, greater than or equal to 4.3 wt. %, greater than or equal to 4.4 wt. %, greater than or equal to 4.6 wt. %, greater than or equal to 4.7 wt. %, greater than or equal to 4.8 wt. %, greater than or equal to 4.9 wt. %, greater than or equal to 5.1 wt. %, or greater than or equal to 5.2 wt. %, or any range or value therein between.

In some embodiments, the abrasive particles are present in the composition at a concentration by weight, relative to the total weight of the composition, of less than or equal to about 10.0 wt. %, less than or equal to about 9.5 wt. %, less than or equal to about 9.0 wt. %, less than or equal to about 8.5 wt. %, less than or equal to about 8.0 wt. %, less than or equal to about 7.5 wt. %, less than or equal to about 7.0 wt. %, less than or equal to about 6.5 wt. %, less than or equal to about 6.0 wt. %, less than or equal to about 5.5 wt. %, less than or equal to about 5.0 wt. %, less than or equal to about 4.5 wt. %, less than or equal to about 4.0 wt. %, less than or equal to about 3.9 wt. %, less than or equal to about 3.8 wt. %, less than or equal to about 3.7 wt. %, less than or equal to about 3.6 wt. %, less than or equal to about 3.5 wt. %, less than or equal to about 3.4 wt. %, less than or equal to about 3.3 wt. %, less than or equal to about 3.2 wt. %, less than or equal to about 3.1 wt. %, less than or equal to about 3.0 wt. %, less than or equal to about 2.9 wt. %, less than or equal to about 2.8 wt. %, less than or equal to about 2.7 wt. %, less than or equal to about 2.6 wt. %, less than or equal to about 2.5 wt. %, less than or equal to about 2.4 wt. %, less than or equal to about 2.3 wt. %, less than or equal to about 2.2 wt. %, less than or equal to about 2.1 wt. %, less than or equal to about 2.0 wt. %, less than or equal to about 1.9 wt. %, less than or equal to about 1.8 wt. %, less than or equal to about 1.7 wt. %, less than or equal to about 1.6 wt. %, less than or equal to about 1.5 wt. %, less than or equal to about 1.4 wt. %, less than or equal to about 1.3 wt. %, less than or equal to about 1.2 wt. %, less than or equal to about 1.1 wt. %, less than or equal to about 1.0 wt. %, less than or equal to about 0.95 wt. %, less than or equal to about 0.9 wt. %, less than or equal to about 0.85 wt. %, less than or equal to about 0.8 wt. %, less than or equal to about 0.75 wt. %, less than or equal to about 0.7 wt. %, less than or equal to about 0.65 wt. %, less than or equal to about 0.6 wt. %, less than or equal to about 0.55 wt. %, less than or equal to about 0.5 wt. %, less than or equal to about 0.45 wt. %, less than or equal to about 0.4 wt. %, less than or equal to about 0.35 wt. %, less than or equal to about 0.3 wt. %, less than or equal to about 0.25 wt. %, less than or equal to about 0.2 wt. %, less than or equal to about 0.15 wt. %, less than or equal to about 0.1 wt. %, or any range or value therein between. In some embodiments, the abrasive particles (abrasive) are present in the composition at a concentration by weight, relative to the total weight of the composition, of less than or equal to 5.4 wt. %, or less than or equal to 5.3 wt. %, or any range or value therein between.

In some embodiments, the abrasive particles are present in the composition at a concentration by weight, relative to the total weight of the composition, of about 0.1 wt. % to about 10.0 wt. %, about 0.2 wt. % to about 10.0 wt. %, about 0.3 wt. % to about 10.0 wt. %, about 0.4 wt. % to about 10.0 wt. %, about 0.5 wt. % to about 10.0 wt. %, about 0.6 wt. % to about 10.0 wt. %, about 0.7 wt. % to about 10.0 wt. %, about 0.8 wt. % to about 10.0 wt. %, about 0.9 wt. % to about 10.0 wt. %, about 1.0 wt. % to about 10.0 wt. %, about 2 wt. % to about 10.0 wt. %, about 2.2 wt. % to about 10.0 wt. %, about 2.5 wt. % to about 10.0 wt. %, about 2.8 wt. % to about 10.0 wt. %, about 3 wt. % to about 10.0 wt. %, about 3.5 wt. % to about 10.0 wt. %, about 4 wt. % to about 10.0 wt. %, about 5 wt. % to about 10.0 wt. %, about 5 wt. % to about 9.5 wt. %, about 5 wt. % to about 9.0 wt. %, about 5 wt. % to about 8.5 wt. %, about 5 wt. % to about 8.0 wt. %, about 5 wt. % to about 7.5 wt. %, about 5 wt. % to about 7.0 wt. %, about 5 wt. % to about 6.5 wt. %, about 4.5 wt. % to about 7.0 wt. %, about 4.0 wt. % to about 7.5 wt. %, about 3.5 wt. % to about 8.0 wt. %, about 3.0 wt. % to about 8.5 wt. %, about 2.5 wt. % to about 9.0 wt. %, about 2.0 wt. % to about 9.5 wt. %, about 1.5 wt. % to about 10.0 wt. %, about 3.0 wt. % to about 5 wt. %, about 0.1 wt. % to about 3.0 wt. %, about 0.2 wt. % to about 3.0 wt. %, about 0.3 wt. % to about 3.0 wt. %, about 0.4 wt. % to about 3.0 wt. %, about 0.5 wt. % to about 3.0 wt. %, about 0.6 wt. % to about 3.0 wt. %, about 0.7 wt. % to about 3.0 wt. %, about 0.8 wt. % to about 3.0 wt. %, about 0.9 wt. % to about 3.0 wt. %, about 1.0 wt. % to about 3.0 wt. %, about 1.2 wt. % to about 3.0 wt. %, about 1.5 wt. % to about 3.0 wt. %, about 1.8 wt. % to about 3.0 wt. %, about 2.0 wt. % to about 3.0 wt. %, about 2.2 wt. % to about 3.0 wt. %, about 2.2 wt. % to about 2.5 wt. %, about 0.1 wt. % to about 2.5 wt. %, about 0.2 wt. % to about 2.5 wt. %, about 0.3 wt. % to about 2.5 wt. %, about 0.4 wt. % to about 2.5 wt. %, about 0.5 wt. % to about 2.5 wt. %, about 0.6 wt. % to about 2.5 wt. %, about 0.7 wt. % to about 2.5 wt. %, about 0.8 wt. % to about 2.5 wt. %, about 0.9 wt. % to about 2.5 wt. %, about 1.0 wt. % to about 2.5 wt. %, about 1.2 wt. % to about 2.5 wt. %, about 1.5 wt. % to about 2.5 wt. %, about 1.8 wt. % to about 2.5 wt. %, about 2.0 wt. % to about 2.5 wt. %, or any range or value therein. In some embodiments, the abrasive particles (abrasive) are present in the composition at a concentration by weight, relative to the total weight of the composition, of 5.1 wt. % to 5.4 wt. %, or any range or value therein between.

In some embodiments, the abrasive particles (e.g., unmodified colloidal silica or anionically-modified colloidal silica) have a negative charge under pH conditions used in the polishing compositions of the present disclosure. In some embodiments, the abrasive particles (e.g., colloidal silica or anionically-modified colloidal silica) have a negative charge under pH of the polishing composition (e.g., between 6.5 and 11, or between 7 and 11). In some embodiments, the zeta potential of the abrasive particles is equal to or more negative than −1 mV, −2 mV, −5 mV, −10 mV, −15 mV, −20 mV, −25 mV, −30 mV, −35 mV, or −40 mV, or any range or value therein between. In some embodiments, the zeta potential of the anionically-modified abrasive particles is a greater negative charge (i.e., is more negative) than a corresponding unmodified abrasive particle (e.g., unmodified colloidal silica) at the same pH conditions. In some embodiments, the zeta potential of the abrasive particles (abrasive) is equal to or more positive than −60 mV, or −50 mV, or any range or value therein between. Note that the zeta potential of the abrasive particles used in Examples is approximately −40 to −50 mV.

In some embodiments, the abrasive particles have an aspect ratio of less than or equal to 2.00, less than or equal to 1.90, less than or equal to 1.80, less than or equal to 1.70, less than or equal to 1.60, less than or equal to 1.50, less than or equal to 1.40, less than or equal to 1.30, less than or equal to 1.20, less than or equal to 1.10, less than or equal to 1.00, or any range or value including and/or in between any two of these values. In some embodiments, the abrasive particles (abrasive) have an aspect ratio of greater than or equal to 1.00.

In some embodiments, the abrasive particles are spherical or approximately spherical. In some embodiments, the abrasive particles are globular particles. For purposes of this disclosure, the term “globular particles” means abrasive particles that are nearly spherical (e.g., having an aspect ratio of 1.2 or less).

In some embodiments, the abrasive particles (abrasive) substantially contain surface-unmodified colloidal silica or surface-modified colloidal silica. As used herein, “substantially” means that greater than or equal to 95 wt. %, preferably greater than or equal to 98 wt. %, and more preferably greater than or equal to 99 wt. % of the particles that make up the abrasive are surface-unmodified colloidal silica or surface-modified colloidal silica, including 100 wt. % of the particles being surface-unmodified colloidal silica or surface-modified colloidal silica.

### Phosphate Surfactant

In some embodiments, a polishing composition according to the present disclosure contains one or more phosphate surfactants. By way of non-limiting example, in some embodiments, the phosphate surfactant contains a polyoxyethylene alkyl ether phosphate or a polyoxyethylene alkenyl ether phosphate. In some embodiments, the polyoxyethylene alkyl ether phosphate may contain a monoester phosphate, diester phosphate, or mixture of the two. In some embodiments, the polyoxyethylene alkyl ether phosphate has the following structure: [(alkyl chain)-(polyethylene oxide)-O]m-phosphoric acid, wherein m is 1 or 2 or 3. In some embodiments the phosphate surfactant has the following formula (I):

[tail-(OC₂H₅)ₙ—O]ₘ—PO_{q}Hᵣ (I),

wherein (OC₂H₅) is an “EO group,” and n is 1, 2, 3, 4 5, 6, 7, 8, 9, 10, 11, 12, 13, 14, 15, or 16. In some embodiments, the number of EO groups is 10 or less. In some embodiments, m is 1, 2, or 3. In some embodiments, r is 0, 1, or 2. In some embodiments, q is 1, 2, or 3.

In some embodiments, the phosphate surfactant contains a polyoxyethylene alkyl phenyl ether phosphate. In some embodiments, the phosphate surfactant contains a polyoxyethylene alkyl phenyl ether phosphate having 5 to 16 oxyethylene units.

In some embodiments, the phosphate surfactant contains a polyoxyethylene alkylphenyl ether phosphate having 1 to 15, 2 to 14, 3 to 13, 4 to 12, 5 to 11, 6 to 10, or 7 to 9 oxyethylene units. In some embodiments, the polyoxyethylene alkyl phenyl ether phosphate has alkyl carbon atoms of 4 to 18, 5 to 17, 6 to 16, 7 to 15, 8 to 14, 8 to 13, 8 to 12, or 8 to 11.

In some embodiments, the phosphate surfactant contains a polyoxyethylene alkenyl ether phosphate. In some embodiments, the phosphate surfactant contains a polyoxyethylene alkenyl ether phosphate having 1 to 15, 2 to 14, 3 to 13, 4 to 12, 4 to 11, 5 to 11, 6 to 10, or 7 to 10 oxyethylene units. In some embodiments, the polyoxyethylene alkenyl ether phosphate has alkenyl carbon atoms of 7 to 25, 8 to 24, 9 to 23, 10 to 22, 11 to 21, 12 to 20, 13 to 19, or 14 to 18.

In some embodiments, (m, q, r) is (1, 3, 2), (2, 2, 1), or (3, 1, 0). In some embodiments, n is independently in each instance selected from the group of 1, 2, 3, 4, 5, 6, 7, 8, 9, or 10. In some embodiments, (m, q, r) is (1, 3, 2). In some embodiments, (m, q, r) is (2, 2, 1). In some embodiments, (m, q, r) is (3, 1, 0). In some embodiments, and (m, q, r) is a mixture of (1, 3, 2), (2, 2, 1), and (3, 1, 0).

In some embodiments, the tail contains a substituted or unsubstituted straight chain or branched alkyl, alkenyl, alkynyl, phenyl, or alkylphenyl C₂₋₂₄ hydrocarbon. In some embodiments, the alkyl tail contains a phenyl group (styrenated phenyl or nonyl phenyl). In some embodiments, the tail contains a hydrocarbon with at least 2, at least 3, at least 4, at least 5, at least 6, at least 7, at least 8, at least 9, at least 10, at least 11, at least 12, at least 13, at least 14, at least 15, at least 16, at least 17, at least 18, at least 19, at least 20, at least 21, at least 22, at least 23, at least 24, or greater number of carbon atoms.

In some embodiments, the phosphate surfactant contains oxyethylene units and alkyl phenyl or alkenyl.

In some embodiments, the phosphate surfactant has oxyethylene units of 1, 2, 3, 4, 5, 6, 7, 8, 9, 10, 11, 12, 13, 14, or 15.

In some embodiments, the alkylphenyl in the phosphate surfactant contains straight chain or branched alkyl of greater than or equal to C₄, greater than or equal to C₅, greater than or equal to C₆, greater than or equal to C₇, or greater than or equal to C₈. In some embodiments, the alkylphenyl in the phosphate surfactant contains straight chain or branched alkyl of less than or equal to C₁₈, less than or equal to C₁₇, less than or equal to C₁₆, less than or equal to C₁₅, less than or equal to C₁₄, less than or equal to C₁₃, less than or equal to C₁₂, less than or equal to C₁₁, or less than or equal to C₁₀.

In some embodiments, the phosphate surfactant contains straight chain or branched alkenyl of greater than or equal to C₇, greater than or equal to C₈, greater than or equal to C₉, greater than or equal to C₁₀, greater than or equal to C₁₁, greater than or equal to C₁₂, greater than or equal to C₁₃, greater than or equal to C₁₄, greater than or equal to C₁₅, greater than or equal to C₁₆, greater than or equal to C₁₇, or greater than or equal to C₁₈. In some embodiments, the phosphate surfactant contains straight chain or branched alkenyl of less than or equal to C₂₅, less than or equal to C₂₄, less than or equal to C₂₃, less than or equal to C₂₂, less than or equal to C₂₁, less than or equal to C₂₀, or less than or equal to C₁₉.

In some embodiments, greater than or equal to 80 wt. %, greater than or equal to 85 wt. %, greater than or equal to 90 wt. %, greater than or equal to 95 wt. %, or greater than or equal to 99 wt. % of the surfactant present in the polishing composition are made up of the phosphate surfactant shown in the above formula (I).

In some embodiments, that the phosphate surfactant has a molecular weight of greater than or equal to about 150 g/mol, greater than or equal to about 200 g/mol, greater than or equal to about 250 g/mol, greater than or equal to about 300 g/mol, greater than or equal to about 350 g/mol, greater than or equal to about 400 g/mol, greater than or equal to about 450 g/mol, greater than or equal to about 500 g/mol, greater than or equal to about 550 g/mol, greater than or equal to about 600 g/mol, greater than or equal to about 650 g/mol, greater than or equal to about 700 g/mol, greater than or equal to about 750 g/mol, greater than or equal to about 800 g/mol, greater than or equal to about 850 g/mol, greater than or equal to about 900 g/mol, greater than or equal to about 950 g/mol, greater than or equal to about 1000 g/mol, greater than or equal to about 1100 g/mol, greater than or equal to about 1200 g/mol, greater than or equal to about 1300 g/mol, greater than or equal to about 1400 g/mol, greater than or equal to about 1500 g/mol, or any range or value therein between.

In some embodiments, the phosphate surfactant contains a polyoxyethylene alkylphenyl ether phosphate or a polyoxyethylene alkenyl ether phosphate. In some embodiments, the phosphate surfactant contains a polyoxyethylene alkylphenyl ether phosphate having 4 to 16 oxyethylene units. In some embodiments, the phosphate surfactant contains at least one of laureth-4 phosphate (e.g., Ethfac 142W), polyoxyethylene (4) nonylphenylphosphate, polyoxyethylene (5) nonylphenylphosphate, polyoxyethylene (7) nonylphenylphosphate (e.g., Ethfac NP-110), polyoxyethylene (10) nonylphenylphosphate, polyoxyethylene (12) nonylphenylphosphate, polyoxyethylene (16) nonylphenylphosphate, polyoxyethylene (7) phenylphosphate, polyoxyethylene (7) dodecylphenylphosphate, polyoxyethylene (7) nonylphosphate, polyoxyethylene (7) propylphenylphosphate, and polyoxyethylene (10) oleyl ether phosphate (e.g., Crodafos O10A), and combinations thereof. In some embodiments, the phosphate surfactant contains polyoxyethylene (7) nonylphenylphosphate (e.g., Ethfac NP-110) or polyoxyethylene (10) nonylphenylphosphate. In some embodiments, the phosphate surfactant contains polyoxyethylene (7) nonylphenylphosphate (e.g., Ethfac NP-110).

In some embodiments, the anionic surfactant (e.g., phosphate surfactant) is present in the composition at a concentration by weight, relative to the total weight of the polishing composition, of greater than or equal to about 0.001 wt. %, greater than or equal to about 0.002 wt. %, greater than or equal to about 0.003 wt. %, greater than or equal to about 0.004 wt. %, greater than or equal to about 0.005 wt. %, greater than or equal to about 0.006 wt. %, greater than or equal to about 0.007 wt. %, greater than or equal to about 0.008 wt. %, greater than or equal to about 0.009 wt. %, greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.06 wt. %, greater than or equal to about 0.07 wt. %, greater than or equal to about 0.08 wt. %, greater than or equal to about 0.09 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1.0 wt. %, or any range or value therein between. In some embodiments, the anionic surfactant (e.g., phosphate surfactant) is present in the composition at a concentration by weight, relative to the total weight of the polishing composition, of greater than 0.005 wt. %.

In some embodiments, the anionic surfactant (e.g., phosphate surfactant) is present in the composition at a concentration by weight, relative to the total weight of the polishing composition, of less than or equal to about 1.0 wt. %, less than or equal to about 0.9 wt. %, less than or equal to about 0.8 wt. %, less than or equal to about 0.7 wt. %, less than or equal to about 0.6 wt. %, less than or equal to about 0.5 wt. %, less than or equal to about 0.4 wt. %, less than or equal to about 0.3 wt. %, less than or equal to about 0.2 wt. %, less than or equal to about 0.1 wt. %, less than or equal to about 0.09 wt. %, less than or equal to about 0.08 wt. %, less than or equal to about 0.07 wt. %, less than or equal to about 0.06 wt. %, less than or equal to about 0.05 wt. %, less than or equal to about 0.04 wt. %, less than or equal to about 0.03 wt. %, less than or equal to about 0.02 wt. %, less than or equal to about 0.01 wt. %, less than or equal to about 0.009 wt. %, less than or equal to about 0.008 wt. %, less than or equal to about 0.007 wt. %, less than or equal to about 0.006 wt. %, less than or equal to about 0.005 wt. %, or any range or value therein between.

In some embodiments, the anionic surfactant (e.g., phosphate surfactant) is present in the composition at a concentration by weight, relative to the total weight of the polishing composition, of about 0.001 wt. % to about 1.0 wt. %, about 0.002 wt. % to about 1.0 wt. %, about 0.003 wt. % to about 1.0 wt. %, about 0.004 wt. % to about 1.0 wt. %, about 0.005 wt. % to about 1.0 wt. %, about 0.006 wt. % to about 1.0 wt. %, about 0.007 wt. % to about 1.0 wt. %, about 0.008 wt. % to about 1.0 wt. %, about 0.009 wt. % to about 1.0 wt. %, about 0.01 wt. % to about 1.0 wt. %, about 0.02 wt. % to about 1.0 wt. %, about 0.03 wt. % to about 1.0 wt. %, about 0.04 wt. % to about 1.0 wt. %, about 0.05 wt. % to about 1.0 wt. %, about 0.06 wt. % to about 1.0 wt. %, about 0.07 wt. % to about 1.0 wt. %, about 0.08 wt. % to about 1.0 wt. %, about 0.09 wt. % to about 1.0 wt. %, about 0.1 wt. % to about 1.0 wt. %, 0.001 wt. % to about 0.5 wt. %, about 0.002 wt. % to about 0.5 wt. %, about 0.003 wt. % to about 0.5 wt. %, about 0.004 wt. % to about 0.5 wt. %, about 0.005 wt. % to about 0.5 wt. %, about 0.006 wt. % to about 0.5 wt. %, about 0.007 wt. % to about 0.5 wt. %, about 0.008 wt. % to about 0.5 wt. %, about 0.009 wt. % to about 0.5 wt. %, about 0.01 wt. % to about 0.5 wt. %, about 0.02 wt. % to about 0.5 wt. %, about 0.03 wt. % to about 0.5 wt. %, about 0.04 wt. % to about 0.5 wt. %, about 0.05 wt. % to about 0.5 wt. %, about 0.06 wt. % to about 0.5 wt. %, about 0.07 wt. % to about 0.5 wt. %, about 0.08 wt. % to about 0.5 wt. %, about 0.09 wt. % to about 0.5 wt. %, about 0.1 wt. % to about 0.5 wt. %, 0.001 wt. % to about 0.3 wt. %, about 0.002 wt. % to about 0.3 wt. %, about 0.003 wt. % to about 0.3 wt. %, about 0.004 wt. % to about 0.3 wt. %, about 0.005 wt. % to about 0.3 wt. %, about 0.006 wt. % to about 0.3 wt. %, about 0.007 wt. % to about 0.3 wt. %, about 0.008 wt. % to about 0.3 wt. %, about 0.009 wt. % to about 0.3 wt. %, about 0.01 wt. % to about 0.3 wt. %, about 0.02 wt. % to about 0.3 wt. %, about 0.03 wt. % to about 0.3 wt. %, about 0.04 wt. % to about 0.3 wt. %, about 0.05 wt. % to about 0.3 wt. %, about 0.06 wt. % to about 0.3 wt. %, about 0.07 wt. % to about 0.3 wt. %, about 0.08 wt. % to about 0.3 wt. %, about 0.09 wt. % to about 0.3 wt. %, about 0.1 wt. % to about 0.3 wt. %, or any range or value therein between.

In some embodiments, the concentration ratio of the abrasive to the surfactant is greater than or equal to about 1, greater than or equal to about 2, greater than or equal to about 3, greater than or equal to about 4, greater than or equal to about 5, greater than or equal to about 6, greater than or equal to about 7, greater than or equal to about 8, greater than or equal to about 9, greater than or equal to about 10, greater than or equal to about 15, greater than or equal to about 20, greater than or equal to about 25, greater than or equal to about 30, greater than or equal to about 35, greater than or equal to about 40, greater than or equal to about 45, greater than or equal to about 50, greater than or equal to about 60, greater than or equal to about 70, greater than or equal to about 80, greater than or equal to about 90, greater than or equal to about 100, greater than or equal to about 200, greater than or equal to about 300, greater than or equal to about 400, greater than or equal to about 500, greater than or equal to about 600, greater than or equal to about 700, greater than or equal to about 800, greater than or equal to about 900, greater than or equal to about 1000, greater than or equal to about 1100, greater than or equal to about 1200, greater than or equal to about 1300, greater than or equal to about 1400, greater than or equal to about 1500, greater than or equal to about 1600, greater than or equal to about 1700, greater than or equal to about 1800, greater than or equal to about 1900, greater than or equal to about 2000, or any range or value including and/or in between any two of these values. Note that the concentration ratio of the abrasive to the surfactant is obtained by the concentration (wt. %) in the polishing composition of the abrasive/the concentration (wt. %) in the polishing composition of the surfactant.

In some embodiments, the concentration ratio of the abrasive to the surfactant is less than or equal to about 2000, less than or equal to about 1900, less than or equal to about 1800, less than or equal to about 1700, less than or equal to about 1600, less than or equal to about 1500, less than or equal to about 1400, less than or equal to about 1300, less than or equal to about 1200, less than or equal to about 1100, less than or equal to about 1000, less than or equal to about 900, less than or equal to about 800, less than or equal to about 700, less than or equal to about 600, less than or equal to about 500, less than or equal to about 400, less than or equal to about 300, less than or equal to about 200, less than or equal to about 100, less than or equal to about 90, less than or equal to about 80, less than or equal to about 70, less than or equal to about 60, less than or equal to about 50, less than or equal to about 45, less than or equal to about 40, less than or equal to about 35, less than or equal to about 30, less than or equal to about 25, less than or equal to about 20, less than or equal to about 15, less than or equal to about 10, less than or equal to about 9, less than or equal to about 8, less than or equal to about 7, less than or equal to about 6, less than or equal to about 5, less than or equal to about 4, less than or equal to about 3, less than or equal to about 2, less than or equal to about 1, or any range or value including and/or in between any two of these values. In some embodiments, the concentration ratio of the abrasive to the surfactant is less than 1040.

### Organic Acids

In some embodiments, the polishing composition according to the present disclosure contains one or more acidic compounds. In some embodiments, the one or more acidic compounds contains one or more organic acids (e.g., carboxylic acids including formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid; organic sulfuric acids including methanesulfonic acid, ethanesulfonic acid, and isethionic acid, and any combinations thereof; and organic phosphonoacetic acids, such as 2-hydroxy phosphonoacetic acid (HPAA); and combinations thereof). In some embodiments, the organic acid is citric acid. In some embodiments, the polishing composition according to the present disclosure contains an organic acid. In some embodiments, the organic acid contains a carboxy group. In some embodiments, the organic acid contains a carboxy group and a hydroxy group. In some embodiments, the organic acid contains two or more carboxy groups and a hydroxy group. In some embodiments, the number of carboxy groups contained in the organic acid is, for example, less than or equal to 5, less than or equal to 4, or less than or equal to 3. In some embodiments, the organic acid has no sulfonic acid group. In some embodiments, the organic acid has no sulfur atom nor phosphorous atom.

In some embodiments, one or more organic acids is present in the polishing composition at a concentration, by weight relative to the total weight of the polishing composition, of about 0.001 wt. % to about 5 wt. %, about 0.01 wt. % to about 0.5 wt. %, about 0.005 wt. % to about 5 wt. %, about 0.01 wt. % to about 5 wt. %, about 0.05 wt. % to about 5 wt. %, about 0.1 wt. % to about 5 wt. %, about 0.5 wt. % to about 5 wt. %, about 1 wt. % to about 5 wt. %, about 0.001 wt. % to about 1 wt. %, about 0.005 wt. % to about 1 wt. %, about 0.01 wt. % to about 1 wt. %, about 0.05 wt. % to about 1 wt. %, about 0.1 wt. % to about 1 wt. %, about 0.5 wt. % to about 1 wt. %, about 0.001 wt. % to about 0.1 wt. %, about 0.005 wt. % to about 0.1 wt. %, about 0.01 wt. % to about 0.1 wt. %, about 0.05 wt. % to about 0.1 wt. %, about 0.001 wt. % to about 0.1%, or any range or value including and/or in between any two of these values (e.g. about 0.001 wt. %, about 0.002 wt. %, about 0.003 wt. %, about 0.004 wt. %, about 0.005 wt. %, about 0.006 wt. %, about 0.007 wt. %, about 0.008 wt. %, about 0.009 wt. %, about 0.01 wt. %, about 0.02 wt. %, about 0.03 wt. %, about 0.04 wt. %, about 0.05 wt. %, about 0.06 wt. %, about 0.07 wt. %, about 0.08 wt. %, about 0.09 wt. %, about 0.1 wt. %, about 0.2 wt. %, about 0.3 wt. %, about 0.4 wt. %, about 0.5 wt. %, about 0.6 wt. %, about 0.7 wt. %, about 0.8 wt. %, about 0.9 wt. %, about 1 wt. %, about 2 wt. %, about 3 wt. %, about 4 wt. %, or about 5 wt. %). In some embodiments, one or more organic acids is present in the polishing composition at a concentration by weight, relative to the total weight of the polishing composition, of greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.06 wt. %, greater than or equal to about 0.07 wt. %, greater than or equal to about 0.08 wt. %, or greater than or equal to about 0.09 wt. %. In some embodiments, one or more organic acids is present in the polishing composition at a concentration by weight, relative to the total weight of the polishing composition, of less than or equal to about 3 wt. %, less than or equal to about 2 wt. %, less than or equal to about 1 wt. %, less than or equal to about 0.9 wt. %, less than or equal to about 0.8 wt. %, less than or equal to about 0.7 wt. %, less than or equal to about 0.6 wt. %, less than or equal to about 0.5 wt. %, less than or equal to about 0.4 wt. %, less than or equal to about 0.3 wt. %, or less than or equal to about 0.2 wt. %.

### Electronic Conductivity (EC) Controller

In some embodiments, a polishing composition according to the present disclosure further contains a salt that functions as an electronic conductivity (EC) controller. The EC controller may be any salt that is suitable for polishing compositions (e.g., for adjusting ionic strength of the composition). For example, in some embodiments, the EC controller is a citrate salt, such as a potassium citrate (e.g., tripotassium citrate) or an ammonium citrate. In some embodiments, the EC controller is a nitrate salt, such as sodium nitrate, potassium nitrate, or ammonium nitrate. In some embodiments, the EC controller is an acetate salt, such as sodium acetate, potassium acetate, or ammonium acetate. In some embodiments, the EC controller is a halide salt (e.g., NaCl or KCl). In some embodiments, the EC controller may contain KHCO₃ or NaHCO₃. The EC controller may also be in the hydrate form prior to addition. In some embodiments, the electronic conductivity (EC) controller is a salt of the organic acid contained in the polishing composition according to the present disclosure.

In some embodiments, the anion (e.g., citrate) of the EC controller is the same as an anion of the organic acid (e.g., citrate in citric acid).

In some embodiments, one or more EC controllers is present at a concentration, by weight, relative to the total weight of the polishing composition, of about 0.001 wt. % to about 5 wt. %, about 0.005 wt. % to about 5 wt. %, about 0.01 wt. % to about 5 wt. %, about 0.05 wt. % to about 5 wt. %, about 0.1 wt. % to about 5 wt. %, about 0.5 wt. % to about 5 wt. %, about 1 wt. % to about 5 wt. %, about 0.001 wt. % to about 1 wt. %, about 0.005 wt. % to about 1 wt. %, about 0.01 wt. % to about 1 wt. %, about 0.05 wt. % to about 1 wt. %, about 0.1 wt. % to about 1 wt. %, about 0.5 wt. % to about 1 wt. %, about 0.001 wt. % to about 0.1 wt. %, about 0.005 wt. % to about 0.1 wt. %, about 0.01 wt. % to about 0.1 wt. %, about 0.05 wt. % to about 0.1 wt. %, about 0.001 wt. % to about 0.1%, or any range or value including and/or in between any two of these values (e.g. about 0.001 wt. %, about 0.002 wt. %, about 0.003 wt. %, about 0.004 wt. %, about 0.005 wt. %, about 0.006 wt. %, about 0.007 wt. %, about 0.008 wt. %, about 0.009 wt. %, about 0.01 wt. %, about 0.02 wt. %, about 0.03 wt. %, about 0.04 wt. %, about 0.05 wt. %, about 0.06 wt. %, about 0.07 wt. %, about 0.08 wt. %, about 0.09 wt. %, about 0.1 wt. %, about 0.2 wt. %, about 0.3 wt. %, about 0.4 wt. %, about 0.5 wt. %, about 0.6 wt. %, about 0.7 wt. %, about 0.8 wt. %, about 0.9 wt. %, about 1 wt. %, about 2 wt. %, about 3 wt. %, about 4 wt. %, or about 5 wt. %). In some embodiments, one or more electronic conductivity (EC) controllers is present at a concentration, by weight, relative to the total weight of the polishing composition, of greater than or equal to about 0.02 wt. %, greater than or equal to about 0.03 wt. %, greater than or equal to about 0.04 wt. %, greater than or equal to about 0.05 wt. %, greater than or equal to about 0.06 wt. %, greater than or equal to about 0.07 wt. %, greater than or equal to about 0.08 wt. %, greater than or equal to about 0.09 wt. %, greater than or equal to about 0.1 wt. %, greater than or equal to about 0.12 wt. %, greater than or equal to about 0.14 wt. %, greater than or equal to about 0.16 wt. %, or greater than or equal to about 0.18 wt. %. In some embodiments, one or more electronic conductivity (EC) controllers such as a salt of the organic acid is present at a concentration, by weight, relative to the total weight of the polishing composition, of less than or equal to about 3 wt. %, less than or equal to about 2 wt. %, less than or equal to about 1 wt. %, less than or equal to about 0.9 wt. %, less than or equal to about 0.8 wt. %, less than or equal to about 0.7 wt. %, less than or equal to about 0.6 wt. %, less than or equal to about 0.5 wt. %, less than or equal to about 0.4 wt. %, less than or equal to about 0.3 wt. %, or less than or equal to about 0.2 wt. %.

### Corrosion Inhibitors

In some embodiments, a polishing composition according to the present disclosure contains a corrosion inhibitor (e.g., Cu corrosion inhibitor). Without being bound by any particular theory, it is contemplated that the corrosion inhibitor passivates a metal surface (e.g., Cu surface) to prevent pitting and other types of corrosion defects during CMP. By way of non-limiting example, in some embodiments, the corrosion inhibitor may contain an azole compound. In some embodiments, the corrosion inhibitor contains one or more of the following: benzotriazole (BTA), 1,2,4-triazole, tetrazole, tolytriazole, 4-carboxybenzotriazole, 5-carboxybenzotriale, mercaptobenzoxazole, 2-mercaptobenzothiazole, 2-mercaptobenzimidazole, and derivatives thereof. In some embodiments, the corrosion inhibitor contains benzotriazole (BTA).

The concentration of the corrosion corrosion inhibitor may be any suitable concentration to prevent corrosion, pitting, or etching of a metal (e.g., Cu) at the pH of the polishing composition. In some embodiments, the corrosion inhibitor is present in the polishing composition at a concentration, relative to the total weight of the polishing composition, of greater than or equal to about 0.001 wt. %, greater than or equal to about 0.002 wt. %, greater than or equal to about 0.003 wt. %, greater than or equal to about 0.004 wt. %, greater than or equal to about 0.005 wt. %, greater than or equal to about 0.006 wt. %, greater than or equal to about 0.007 wt. %, greater than or equal to about 0.008 wt. %, greater than or equal to about 0.009 wt. %, greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.06 wt. %, greater than or equal to about 0.07 wt. %, greater than or equal to about 0.08 wt. %, greater than or equal to about 0.09 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1 wt. %, or any range or value including and/or in between any two of these values.

In some embodiments, the corrosion inhibitor is present in the polishing composition at a concentration, relative to the total weight of the polishing composition, of less than or equal to about 1 wt. %, less than or equal to about 0.9 wt. %, less than or equal to about 0.8 wt. %, less than or equal to about 0.7 wt. %, less than or equal to about 0.6 wt. %, less than or equal to about 0.5 wt. %, less than or equal to about 0.4 wt. %, less than or equal to about 0.3 wt. %, less than or equal to about 0.2 wt. %, less than or equal to about 0.1 wt. %, less than or equal to about 0.09 wt. %, less than or equal to about 0.08 wt. %, less than or equal to about 0.07 wt. %, less than or equal to about 0.06 wt. %, less than or equal to about 0.05 wt. %, less than or equal to about 0.04 wt. %, less than or equal to about 0.03 wt. %, less than or equal to about 0.02 wt. %, less than or equal to about 0.01 wt. %, or any range or value including and/or in between any two of these values.

In some embodiments, the corrosion inhibitor is present in the polishing composition at a concentration, relative to the total weight of the polishing composition, of about 0.001 wt. % to about 1 wt. %, about 0.002 wt. % to about 1 wt. %, about 0.003 wt. % to about 1 wt. %, about 0.004 wt. % to about 1 wt. %, about 0.005 wt. % to about 1 wt. %, about 0.006 wt. % to about 1 wt. %, about 0.007 wt. % to about 1 wt. %, about 0.008 wt. % to about 1 wt. %, about 0.009 wt. % to about 1 wt. %, about 0.01 wt. % to about 1 wt. %, about 0.02 wt. % to about 1 wt. %, about 0.03 wt. % to about 1 wt. %, about 0.04 wt. % to about 1 wt. %, about 0.05 wt. % to about 1 wt. %, about 0.06 wt. % to about 1 wt. %, about 0.07 wt. % to about 1 wt. %, about 0.08 wt. % to about 1 wt. %, about 0.09 wt. % to about 1 wt. %, about 0.1 wt. % to about 1 wt. %, about 0.2 wt. % to about 1 wt. %, about 0.3 wt. % to about 1 wt. %, about 0.4 wt. % to about 1 wt. %, about 0.5 wt. % to about 1 wt. %, about 0.001 wt. % to about 0.5 wt. %, about 0.002 wt. % to about 0.5 wt. %, about 0.003 wt. % to about 0.5 wt. %, about 0.004 wt. % to about 0.5 wt. %, about 0.005 wt. % to about 0.5 wt. %, about 0.006 wt. % to about 0.5 wt. %, about 0.007 wt. % to about 0.5 wt. %, about 0.008 wt. % to about 0.5 wt. %, about 0.009 wt. % to about 0.5 wt. %, about 0.01 wt. % to about 0.5 wt. %, about 0.02 wt. % to about 0.5 wt. %, about 0.03 wt. % to about 0.5 wt. %, about 0.04 wt. % to about 0.5 wt. %, about 0.05 wt. % to about 0.5 wt. %, about 0.06 wt. % to about 0.5 wt. %, about 0.07 wt. % to about 0.5 wt. %, about 0.08 wt. % to about 0.5 wt. %, about 0.09 wt. % to about 0.5 wt. %, about 0.1 wt. % to about 0.5 wt. %, about 0.2 wt. % to about 0.5 wt. %, about 0.3 wt. % to about 0.5 wt. %, about 0.001 wt. % to about 0.2 wt. %, about 0.002 wt. % to about 0.2 wt. %, about 0.003 wt. % to about 0.2 wt. %, about 0.004 wt. % to about 0.2 wt. %, about 0.005 wt. % to about 0.2 wt. %, about 0.006 wt. % to about 0.2 wt. %, about 0.007 wt. % to about 0.2 wt. %, about 0.008 wt. % to about 0.2 wt. %, about 0.009 wt. % to about 0.2 wt. %, about 0.01 wt. % to about 0.2 wt. %, about 0.02 wt. % to about 0.2 wt. %, about 0.03 wt. % to about 0.2 wt. %, about 0.04 wt. % to about 0.2 wt. %, about 0.05 wt. % to about 0.2 wt. %, about 0.06 wt. % to about 0.2 wt. %, about 0.07 wt. % to about 0.2 wt. %, about 0.08 wt. % to about 0.2 wt. %, about 0.09 wt. % to about 0.2 wt. %, about 0.1 wt. % to about 0.2 wt. %, about 0.001 wt. % to about 0.1 wt. %, about 0.002 wt. % to about 0.1 wt. %, about 0.003 wt. % to about 0.1 wt. %, about 0.004 wt. % to about 0.1 wt. %, about 0.005 wt. % to about 0.1 wt. %, about 0.006 wt. % to about 0.1 wt. %, about 0.007 wt. % to about 0.1 wt. %, about 0.008 wt. % to about 0.1 wt. %, about 0.009 wt. % to about 0.1 wt. %, about 0.01 wt. % to about 0.1 wt. %, about 0.02 wt. % to about 0.1 wt. %, about 0.03 wt. % to about 0.1 wt. %, about 0.04 wt. % to about 0.1 wt. %, about 0.05 wt. % to about 0.1 wt. %, or any range or value including and/or in between any two of these values.

### Water-Soluble Polymers

In some embodiments, the polishing composition according to the present disclosure contains one or more water-soluble polymers. In some embodiments, the water-soluble polymer refers to a polymer that is, for example, in solid form (powder form) at 25° C., and that can be dissolved in water to become liquid. Water-soluble polymer-containing solutions can be prepared by dissolving water-soluble polymers in water. Here, the term “water-soluble” means the solubility to water (25° C.) is greater than or equal to 1 g/100 mL, and the term “polymer” refers to a (co)polymer that has repeating units in its molecular structure, and in which the weight-average molecular weight (Mw) is greater than or equal to 1,000. As used herein, the “weight-average molecular weight” can be expressed as a value of weight-average molecular weight (in terms of polyethylene glycol) measured by gel permeation chromatography (GPC). The weight-average molecular weight can be measured using the following instruments and conditions:
GPC instrument: manufactured by Shimadzu Corporation
Model type: Prominence+ELSD detector (ELSD-LTII)
Column: VP-ODS (manufactured by Shimadzu Corporation)
Mobile phase A: MeOH
   B: acetic acid 1% aqueous solution
Flow rate: 1 mL/min
Detector: ELSD temp. 40° C., Gain 8, N2GAS 350 kPa
Oven temperature: 40° C.
Amount to be infused: 40 μL

The one or more water-soluble polymers is not particularly limited. Non-limiting examples of the water soluble polymer include one or more polysaccharides (e.g., alginic acid, pectic acid, agar, curdlan and pullulan); cellulose derivatives (e.g., hydroxymethyl cellulose, hydroxyethyl cellulose (HEC), hydroxypropyl cellulose, hydroxyethylmethyl cellulose, hydroxypropylmethyl cellulose, methyl cellulose, ethyl cellulose, ethylhydroxyethyl cellulose, or carboxymethyl cellulose; an imine derivative such as poly(N-acylalkyleneimine); polyvinyl alcohol (PVA); modified (cation modified or non-ion modified) polyvinyl alcohol; poly(N-vinylacetamide) (PNVA); polyvinyl pyrrolidone (PVP); polyvinylcaprolactam; polyoxyalkylenes (e.g., polyoxyethylene); polypropylene glycol (PPG), polyethylene glycol (PEG), PEG-PPG copolymers or block copolymers (e.g., PEG-PPG, PEG-PPG-PEG, PPG-PEG-PPG, etc.), and copolymers or mixtures thereof. In some embodiments, the water-soluble polymer contains pullulan. The one or more water-soluble polymers may be used alone or as a mixture of two or more types of water-soluble polymers.

In some embodiments, the water-soluble polymer contained in the polishing composition according to the present disclosure includes a polysaccharide. In some embodiments, the water-soluble polymer contained in the polishing composition according to the present disclosure includes a polysaccharide consisting only of glucose. In some embodiments, the water-soluble polymers contained in the polishing composition according to the present disclosure includes pullulan. In some embodiments, greater than or equal to 80 wt. %, greater than or equal to 85 wt. %, greater than or equal to 90 wt. %, greater than or equal to 95 wt. %, or greater than or equal to 99 wt. % of the water-soluble polymer contained in the polishing composition according to the present disclosure are made up of polysaccharides. Here, the polysaccharide is a general term for substances in which a large number of monosaccharide molecules are polymerized by glycosidic bonds. The concept of the polysaccharide includes sugar in which a plurality of (two or more) monosaccharides are bound.

In some embodiments, greater than or equal to 80 wt. %, greater than or equal to 85 wt. %, greater than or equal to 90 wt. %, greater than or equal to 95 wt. %, or greater than or equal to 99 wt. % of the water-soluble polymer contained in the polishing composition according to the present disclosure are made up of polysaccharides consisting only of glucose (e.g., pullulan).

In some embodiments, the water-soluble polymer has a molecular weight of greater than or equal to about 500 g/mol, greater than or equal to about 1000 g/mol, greater than or equal to about 1500 g/mol, greater than or equal to about 2000 g/mol, greater than or equal to about 2500 g/mol, greater than or equal to about 3000 g/mol, greater than or equal to about 3500 g/mol, greater than or equal to about 4000 g/mol, greater than or equal to about 4500 g/mol, greater than or equal to about 5000 g/mol, greater than or equal to about 5500 g/mol, greater than or equal to about 6000 g/mol, greater than or equal to about 6500 g/mol, greater than or equal to about 7000 g/mol, greater than or equal to about 7500 g/mol, greater than or equal to about 8000 g/mol, greater than or equal to about 8500 g/mol, greater than or equal to about 9000 g/mol, greater than or equal to about 9500 g/mol, greater than or equal to about 10000 g/mol, greater than or equal to about 15000 g/mol, greater than or equal to about 20000 g/mol, greater than or equal to about 25000 g/mol, greater than or equal to about 30000 g/mol, greater than or equal to about 35000 g/mol, greater than or equal to about 40000 g/mol, greater than or equal to about 45000 g/mol, greater than or equal to about 50000 g/mol, greater than or equal to about 55000 g/mol, greater than or equal to about 60000 g/mol, greater than or equal to about 65000 g/mol, greater than or equal to about 70000 g/mol, greater than or equal to about 75000 g/mol, greater than or equal to about 80000 g/mol, greater than or equal to about 85000 g/mol, greater than or equal to about 90000 g/mol, greater than or equal to about 95000 g/mol, greater than or equal to about 100000 g/mol, greater than or equal to about 150000 g/mol, greater than or equal to about 200000 g/mol, greater than or equal to about 250000 g/mol, greater than or equal to about 300000 g/mol, greater than or equal to about 350000 g/mol, greater than or equal to about 400000 g/mol, greater than or equal to about 450000 g/mol, greater than or equal to about 500000 g/mol, or any range or value including and/or in between any two of these values (e.g., 5,000 to 300,000 g/mol).

In some embodiments, the one or more water-soluble polymers is present at a concentration, by weight, relative to the total weight of the polishing composition, of about 0.001 wt. % to about 5 wt. %, about 0.01 wt. % to about 0.5 wt. %, about 0.005 wt. % to about 5 wt. %, about 0.01 wt. % to about 5 wt. %, about 0.05 wt. % to about 5 wt. %, about 0.1 wt. % to about 5 wt. %, about 0.5 wt. % to about 5 wt. %, about 1 wt. % to about 5 wt. %, about 0.001 wt. % to about 1 wt. %, about 0.005 wt. % to about 1 wt. %, about 0.01 wt. % to about 1 wt. %, about 0.05 wt. % to about 1 wt. %, about 0.1 wt. % to about 1 wt. %, about 0.5 wt. % to about 1 wt. %, about 0.001 wt. % to about 0.1 wt. %, about 0.005 wt. % to about 0.1 wt. %, about 0.01 wt. % to about 0.1 wt. %, about 0.05 wt. % to about 0.1 wt. %, about 0.001 wt. % to about 0.1 wt. %, or any range or value including and/or in between any two of these values (e.g. about 0.001 wt. %, about 0.002 wt. %, about 0.003 wt. %, about 0.004 wt. %, about 0.005 wt. %, about 0.006 wt. %, about 0.007 wt. %, about 0.008 wt. %, about 0.009 wt. %, about 0.01 wt. %, about 0.02 wt. %, about 0.03 wt. %, about 0.04 wt. %, about 0.05 wt. %, about 0.06 wt. %, about 0.07 wt. %, about 0.08 wt. %, about 0.09 wt. %, about 0.1 wt. %, about 0.2 wt. %, about 0.3 wt. %, about 0.4 wt. %, about 0.5 wt. %, about 0.6 wt. %, about 0.7 wt. %, about 0.8 wt. %, about 0.9 wt. %, about 1 wt. %, about 2 wt. %, about 3 wt. %, about 4 wt. %, or about 5 wt. %).

In some embodiments, the water-soluble polymers is present at a concentration, by weight, relative to the total weight of the polishing composition, of greater than or equal to about 0.001 wt. %, greater than or equal to about 0.002 wt. %, greater than or equal to about 0.003 wt. %, greater than or equal to about 0.004 wt. %, greater than or equal to about 0.005 wt. %, greater than or equal to about 0.006 wt. %, greater than or equal to about 0.007 wt. %, greater than or equal to about 0.008 wt. %, greater than or equal to about 0.009 wt. %, or greater than or equal to about 0.01 wt. %, or any range or value including and/or in between any two of these values. In some embodiments, the water-soluble polymers is present at a concentration, by weight, relative to the total weight of the polishing composition, of less than or equal to 5 wt. %, less than or equal to 4 wt. %, less than or equal to 3 wt. %, less than or equal to 2 wt. %, less than or equal to 1 wt. %, less than or equal to 0.9 wt. %, less than or equal to 0.7 wt. %, less than or equal to 0.5 wt. %, less than or equal to 0.3 wt. %, or less than or equal to 0.1 wt. %, or any range or value including and/or in between any two of these values.

### Oxidizers

In some embodiments, the polishing compositions of the present disclosure may contain at least one oxidizer. An oxidizer may be added to the present polishing composition to oxidize a metal surface (e.g., Cu) of a polishing object, thereby enhancing the metal removal rate of the polishing process. In some embodiments, an oxidizer is added to the polishing composition only immediately prior to use (e.g., at “point of use” or “POU”). In other embodiments, an oxidizer is mixed with other ingredients of the polishing composition at approximately the same time during a manufacturing procedure. In some embodiments, the present composition is manufactured and sold as a stock composition, and an end customer can choose to dilute the stock composition as needed and/or add a suitable amount of an oxidizer before using.

In some embodiments, non-limiting examples of the oxidizer which may be used include, but are not limited to, a peroxide (e.g., hydrogen peroxide, sodium peroxide, barium peroxide, etc.), an organic oxidizer, ozone water, a silver (II) salt, an iron (III) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, and a salt thereof. The oxidizer may be used either singly or as a mixture of two or more kinds. In some embodiments, the oxidizer contains, hydrogen peroxide, ammonium persulfate, periodic acid, hypochlorous acid, sodium dichloroisocyanurate, or mixtures thereof. In some embodiments, the oxidizer contains hydrogen peroxide (e.g., 30% H₂02). In some embodiments, greater than or equal to 80 wt. %, greater than or equal to 85 wt. %, greater than or equal to 90 wt. %, greater than or equal to 95 wt. %, or greater than or equal to 99 wt. % of the oxidizer contained in the polishing composition according to the present disclosure are made up of hydrogen peroxide.

In some embodiments, the one or more oxidizers are present in the composition at a concentration by weight, relative to the total weight of the composition, of greater than or equal to about 0.1 wt. %, greater than or equal to about 0.15 wt. %, greater than or equal to about 0.2 wt. %, greater than or equal to about 0.25 wt. %, greater than or equal to about 0.3 wt. %, greater than or equal to about 0.35 wt. %, greater than or equal to about 0.4 wt. %, greater than or equal to about 0.45 wt. %, greater than or equal to about 0.5 wt. %, greater than or equal to about 0.55 wt. %, greater than or equal to about 0.60 wt. %, greater than or equal to about 0.65 wt. %, greater than or equal to about 0.7 wt. %, greater than or equal to about 0.75 wt. %, greater than or equal to about 0.8 wt. %, greater than or equal to about 0.85 wt. %, greater than or equal to about 0.9 wt. %, greater than or equal to about 0.95 wt. %, greater than or equal to about 1.0 wt. %, greater than or equal to about 1.1 wt. %, greater than or equal to about 1.2 wt. %, greater than or equal to about 1.3 wt. %, greater than or equal to about 1.4 wt. %, greater than or equal to about 1.5 wt. %, greater than or equal to about 1.6 wt. %, greater than or equal to about 1.7 wt. %, greater than or equal to about 1.8 wt. %, greater than or equal to about 1.9 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value including and/or in between any two of these values. In some embodiments, one or more oxidizers may be in the form of aqueous solution, in which the effective concentration of the oxidizer may be, for example, 10 to 40 wt. %, or 15 to 35 wt. %. In some embodiments, one or more oxidizers are present in the composition at a concentration by weight, relative to the total weight of the composition, of less than or equal to 10 wt. %, less than or equal to 9 wt. %, less than or equal to 8 wt. %, less than or equal to 7 wt. %, less than or equal to 6 wt. %, less than or equal to 5 wt. %, less than or equal to 4 wt. %, less than or equal to 3 wt. %, or less than or equal to 2 wt. %, or any range or value including and/or in between any two of these values.

As the content of the one or more oxidizers decreases, the cost involved with materials of the polishing composition can be saved and a load involved with waste treatment after use of the polishing composition can be reduced. It is also possible to reduce the possibility of excessive oxidation of a surface by reducing the content of an oxidizer.

### pH Adjusting Agent

In some embodiments, a composition according to the present disclosure may further contain one or more pH adjusting agents to adjust the pH to a selected pH value. In some embodiments, the abrasive, surfactant, corrosion inhibitor, EC controller, organic acid, and water-soluble polymer, discussed above, and “additional ingredients,” discussed below, are not considered to be pH adjusting agent(s).

The pH adjusting agent is not particularly limited, and any suitable pH adjusting agent may be used to bring the pH of the composition into any desired range, as discussed above. In some embodiments, the one or more pH adjusting agents may contain, consist essentially of, or consist of an inorganic compound, an organic compound, or combinations thereof.

In some embodiments, the one or more pH adjusting agents may contain one or more hydroxides of alkali metals (e.g., NaOH, KOH), or salts thereof (e.g., carbonates, hydrogen carbonates, sulfates, acetates, etc.); quaternary ammonium compounds (e.g., tetramethylammonium, tetraethylammonium, tetrabutylammonium, etc.); quaternary ammonium hydroxides (e.g., tetramethylammonium hydroxide, tetraethylammonium hydroxide, tetrabutylammonium hydroxide) or a salts thereof; ammonia; amines; or any other suitable pH adjusting agent.

In some embodiments, one or more pH adjusting agents may contain inorganic acids (e.g., hydrochloric acid, hydrobromic acid, hydroiodic acid, sulfuric acid, nitric acid, boric acid, carbonic acid, hypophosphorous acid, phosphorous acid, and phosphoric acid); and/or organic sulfuric acids (e.g., methane sulfonic acid, ethane sulfonic acid, isethionate, etc.). In some embodiments, the one or more pH adjusting agents may contain a divalent or higher acid of the above acid(s) (e.g., sulfuric acid, carbonic acid, phosphoric acid, oxalic acid, etc.), which may be in the form of a base when one or more protons (H⁺) can be released (e.g., ammonium hydrogen carbonate or ammonium hydrogen phosphate), but any counter-ion may be used (e.g., weakly basic cations, such as ammonium, triethanolamine, etc.).

In some embodiments, the pH adjuster contains NaOH. In some embodiments, the pH adjuster contains KOH. In some embodiments, the pH adjuster contains NaOH, KOH, or a combination thereof.

### pH of Polishing Composition

The pH adjust agent may be present in any amount suitable to achieve a desired Cu, Ta, or TEOS removal rate with satisfactory topography correction and/or flatness. The pH of the polishing composition may be measured using any suitable method known in the art (e.g., using a ThermoFisher Scientific ORION™ VERSA STAR PRO™ pH/ISE/conductivity/dissolved oxygen multiparameter benchtop meter).

In some embodiments, the pH of the composition is less than or equal to about 11, less than or equal to about 10.5, less than or equal to about 10, less than or equal to about 9.5, less than or equal to about 9, less than or equal to about 8.5, less than or equal to about 8, less than or equal to about 7.5, less than or equal to about 7, less than or equal to about 6.5, less than or equal to about 6, less than or equal to about 5.5, less than or equal to about 5, less than or equal to about 4.5, less than or equal to about 4, less than or equal to about 3.5, less than or equal to about 3, less than or equal to about 2.5, less than or equal to about 2, less than or equal to about 1.5, less than or equal to about 1, or any range or value including and/or in between any two of these values.

In some embodiments, the pH of the composition is greater than or equal to about 1, greater than or equal to about 1.5, greater than or equal to about 2, greater than or equal to about 2.5, greater than or equal to about 3, greater than or equal to about 3.5, greater than or equal to about 4, greater than or equal to about 4.5, greater than or equal to about 5, greater than or equal to about 5.5, greater than or equal to about 6, greater than or equal to about 6.5, greater than or equal to about 7, greater than or equal to about 7.5, greater than or equal to about 8, greater than or equal to about 8.5, greater than or equal to about 9, greater than or equal to about 9.5, greater than or equal to about 10, greater than or equal to about 10.5, greater than or equal to about 11, or any range or value including and/or in between any two of these values.

In some embodiments, the pH of the composition is about 1 to about 11.0, about 1 to about 10.5, about 1 to about 10.0, about 1 to about 9.5, about 1 to about 9.0, about 1 to about 8.5, about 1 to about 8.0, about 1.5 to about 11.0, about 1.5 to about 10.5, about 1.5 to about 10.0, about 1.5 to about 9.5, about 1.5 to about 9.0, about 1.5 to about 8.5, about 1.5 to about 8.0, about 2.0 to about 11.0, about 2.0 to about 10.5, about 2.0 to about 10.0, about 2.0 to about 9.5, about 2.0 to about 9.0, about 2.0 to about 8.5, about 2.0 to about 8.0, about 9.0 to about 11.0, about 8.0 to about 12.0, about 7.0 to about 13.0, or any range or value including and/or in between any two of these values.

### Liquid Carrier

Polishing compositions according to the present disclosure may contain a liquid carrier. The liquid carrier of the polishing composition is not particularly limited. In some embodiments, the liquid carrier is water, such as deionized water. The liquid carrier may also be an aqueous solution that has, e.g., an appropriate pH modifier contained therein. In some embodiments, the liquid carrier can contain one or more organic solvents, such as an alcohol compound, e.g., glycol ethers of aliphatic alcohols and 3 to 10 carbon atoms having 2 to 6 carbon atoms. Examples of aliphatic alcohols with 2 to 6 carbon atoms include ethanol, 1-propanol, 2-propanol, 1-butanol, 2-butanol, tert-butanol, pentanol, hexanol, ethylene glycol, propylene glycol, 1,3-butanediol, 1,4-butanediol, 1,5-pentanediol, 1,6-hexanediol, glycerin, 1,2,4-butanetriol, 1,2,6-hexanetriol, erythritol, D-threitol, L-threitol, D-arabinitol, L-arabinitol, ribitol, xylitol, mannitol, and sorbitol. Examples of glycol ethers with 3 to 10 carbon atoms include methyl glycol, methyl diglycol, methyl triglycol, isopropyl glycol, isopropyl diglycol, butyl glycol, butyl diglycol, butyl triglycol, isobutyl glycol, isobutyl diglycol, hexyl glycol, hexyl diglycol, 2-ethylhexyl glycol, 2-ethylhexyl diglycol, aryl glycol, phenyl glycol, phenyl diglycol, benzyl glycol, methylpropylene glycol, methylpropylene diglycol, methylpropylene triglycol, propylpropylene glycol, propylpropylene diglycol, butylpropylene glycol, butylpropylene diglycol, and phenylpropylene glycol. In some embodiments, greater than or equal to 80 wt. %, greater than or equal to 85 wt. %, greater than or equal to 90 wt. %, greater than or equal to 95 wt. %, or greater than or equal to 99 wt. % of the liquid carrier contained in the polishing composition are made up of water.

### Additional Ingredients

In some embodiments, the composition may contain other additives at any concentration. However, it is desirable not to add unnecessary components, which may cause the presence of surface defects. Thus, it is preferred that any other additives are present in relatively small concentrations (e.g., 0.1 wt. % or less, 0.05 wt. % or less, 0.01 wt. % or less, 0.005 wt. % or less, 0.001 wt. % or less, 0.0005 wt. % or less, 0.0001 wt. % or less, 0.0001 wt. % to 0.1 wt. %, 0.0001 wt. % to 0.01 wt. %, or 0.0001 wt. % to 0.001 wt. %, etc.) if they are present at all. Examples of other additives include antiseptic agents, antifungal agents, biocides (e.g., isothiazolinones such as methylisothiazolinone (“MIT”), benzisothiazolinone (“BIT”), 2-methyl-4-isothiazolin-3-one, etc.), dispersants (additives that improve the redispersibility of abrasive grains that have once settled), abrasive grains other than the abrasive grains mentioned above, surfactants other than the surfactants mentioned above, chelating agents, reducing agents, and dissolved gases.

### Method of Producing Polishing Composition

The method of producing the polishing composition according to the present disclosure is not particularly limited, and for example, it can be obtained by stirring and mixing each ingredient in water. The detail of each ingredient is as defined above. The temperature for mixing each ingredient is not particularly limited, preferably greater than or equal to 10° C. and less than or equal to 40° C., and heating can be performed to increase the dissolution rate. In addition, the mixing duration is not particularly limited as long as homogeneous mixture can be achieved.

### Polishing Methods

In another aspect, which may be combined with any other aspect or embodiment, the present disclosure relates to a method of polishing a substrate surface, wherein the substrate surface contains one or two or more of Cu, Ta, SiCN, and TEOS, the method containing: applying the polishing composition according to the above aspects or embodiments to the substrate surface to polish.

In another aspect, which may be combined with any other aspect or embodiment, the present disclosure relates to a method of polishing a substrate surface, wherein the substrate surface contains two or more of Cu, Ta, SiCN, and TEOS, the method containing: contacting the substrate surface with the polishing composition according to any of the embodiments disclosed herein and a polishing pad; and moving the polishing pad against the substrate surface while the polishing composition is in contact with the substrate surface; wherein A2/A3 is 0.85 or greater. In some embodiments, the substrate surface contains Cu and TEOS. In some embodiments, the substrate surface contains Cu, Ta, SiCN, and TEOS. In some embodiments, the substrate surface contains Cu, Ta, and TEOS.

### Flatness

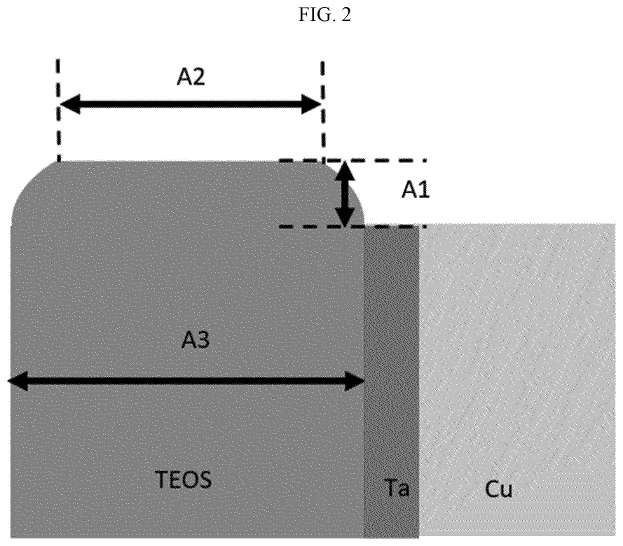

Polishing compositions according to the present disclosure achieve a high degree of flatness on patterned substrates (e.g., patterned substrates containing TEOS, Cu, and Ta). Referring to FIG. 2, flatness may be determined by measuring the width of the top of a TEOS feature (A2), the height of the top of a TEOS feature relative to the top of an adjacent Ta or Cu feature (A1). Given a known width of a TEOS feature (A3), the flatness is calculated using Equation 2 below

$$Flatness = ( A 3 - A 2 ) \times ( 0.5 \times A 1 ) \qquad ( 2 )$$

In some embodiments, the polishing achieves a flatness of the substrate surface of less than or equal to 20, wherein the flatness is defined by (A3−A2)×(0.5×A1). In some embodiments, the flatness is less than or equal to 10. In some embodiments, the flatness is less than or equal to about 20, less than or equal to about 19, less than or equal to about 18, less than or equal to about 17, less than or equal to about 16, less than or equal to about 15, less than or equal to about 14, less than or equal to about 13, less than or equal to about 12, less than or equal to about 11, less than or equal to about 10, less than or equal to about 9, less than or equal to about 8, less than or equal to about 7, less than or equal to about 6, less than or equal to about 5, less than or equal to about 4, less than or equal to about 3, less than or equal to about 2, less than or equal to about 1, or any range or value including and/or in between any two of these values. In some embodiments, the flatness is less than or equal to about 90, less than or equal to about 80, less than or equal to about 70, less than or equal to about 60, less than or equal to about 50, less than or equal to about 40, or less than or equal to about 30.

In some embodiments, the ratio of A2/A3 is greater than or equal to about 0.87, greater than or equal to about 0.89, greater than or equal to about 0.91, greater than or equal to about 0.93, greater than or equal to about 0.94, or greater than or equal to about 0.96, or any range or value including and/or in between any two of these values. In some embodiments, the ratio of A2/A3 is less than 1.00. In some embodiments, the ratio of A2/A3 is greater than or equal to about 50, greater than or equal to about 55, greater than or equal to about 60, greater than or equal to about 65, greater than or equal to about 70, greater than or equal to about 75, greater than or equal to about 80, greater than or equal to about 85, greater than or equal to about 90, greater than or equal to about 95, greater than or equal to about 96, greater than or equal to about 97, greater than or equal to about 98, greater than or equal to about 99, or any range or value including and/or in between any two of these values.

### Removal Rates

In some embodiments, polishing compositions according to the present disclosure achieve a TEOS removal rate (RR_{TEOS}) of greater than or equal to about 10 nm/min, greater than or equal to about 15 nm/min, greater than or equal to about 20 nm/min, greater than or equal to about 25 nm/min, greater than or equal to about 30 nm/min, greater than or equal to about 35 nm/min, greater than or equal to about 40 nm/min, greater than or equal to about 45 nm/min, greater than or equal to about 50 nm/min, greater than or equal to about 55 nm/min, greater than or equal to about 60 nm/min, greater than or equal to about 65 nm/min, greater than or equal to about 70 nm/min, greater than or equal to about 75 nm/min, greater than or equal to about 80 nm/min, greater than or equal to about 85 nm/min, greater than or equal to about 90 nm/min, greater than or equal to about 95 nm/min, greater than or equal to about 100 nm/min, or any range or value including and/or in between any two of these values. In some embodiments, polishing compositions according to the present disclosure achieve a TEOS removal rate (RR_{TEOS}) of less than or equal to about 90 nm/min, less than or equal to about 80 nm/min, less than or equal to about 70 nm/min, or less than or equal to about 60 nm/min, or any range or value including and/or in between any two of these values.

In some embodiments, polishing compositions according to the present disclosure achieve a Cu removal rate (RR_{Cu}) of greater than or equal to about 30 nm/min, greater than or equal to about 35 nm/min, greater than or equal to about 40 nm/min, greater than or equal to about 45 nm/min, greater than or equal to about 50 nm/min, greater than or equal to about 55 nm/min, greater than or equal to about 60 nm/min, greater than or equal to about 65 nm/min, greater than or equal to about 70 nm/min, greater than or equal to about 75 nm/min, greater than or equal to about 80 nm/min, greater than or equal to about 85 nm/min, greater than or equal to about 90 nm/min, greater than or equal to about 95 nm/min, greater than or equal to about 100 nm/min, or any range or value including and/or in between any two of these values. In some embodiments, polishing compositions according to the present disclosure achieve a Cu removal rate (RR_{Cu}) of less than or equal to about 90 nm/min, less than or equal to about 80 nm/min, less than or equal to about 70 nm/min, or less than or equal to about 60 nm/min, or any range or value including and/or in between any two of these values.

In some embodiments, polishing compositions according to the present disclosure achieve a Ta removal rate (RR_{Ta}) of greater than or equal to about 30 nm/min, greater than or equal to about 35 nm/min, greater than or equal to about 40 nm/min, greater than or equal to about 45 nm/min, greater than or equal to about 50 nm/min, greater than or equal to about 55 nm/min, greater than or equal to about 60 nm/min, greater than or equal to about 65 nm/min, greater than or equal to about 70 nm/min, greater than or equal to about 75 nm/min, greater than or equal to about 80 nm/min, greater than or equal to about 85 nm/min, greater than or equal to about 90 nm/min, greater than or equal to about 95 nm/min, greater than or equal to about 100 nm/min, or any range or value including and/or in between any two of these values. In some embodiments, polishing compositions according to the present disclosure achieve a Ta removal rate (RR_{Ta}) of less than or equal to about 120 nm/min, less than or equal to about 100 nm/min, less than or equal to about 80 nm/min, or less than or equal to about 60 nm/min, or any range or value including and/or in between any two of these values.

In some embodiments, polishing compositions according to the present disclosure achieve a SiCN removal rate (RR_{SiCN}) of greater than or equal to about 10 nm/min, greater than or equal to about 15 nm/min, greater than or equal to about 20 nm/min, greater than or equal to about 25 nm/min, greater than or equal to about 30 nm/min, greater than or equal to about 35 nm/min, greater than or equal to about 40 nm/min, greater than or equal to about 45 nm/min, greater than or equal to about 50 nm/min, greater than or equal to about 55 nm/min, greater than or equal to about 60 nm/min, greater than or equal to about 65 nm/min, greater than or equal to about 70 nm/min, greater than or equal to about 75 nm/min, greater than or equal to about 80 nm/min, greater than or equal to about 85 nm/min, greater than or equal to about 90 nm/min, greater than or equal to about 95 nm/min, greater than or equal to about 100 nm/min, or any range or value including and/or in between any two of these values.

The present disclosure encompasses the following aspects and embodiments.

1. A polishing composition, comprising: an abrasive, wherein the abrasive has a mean particle size (MPS) of 100 nm to 150 nm; a phosphate surfactant; an electronic conductivity (EC) controller; an organic acid; and a water-soluble polymer, wherein a ratio of a concentration of the abrasive to a concentration of the phosphate surfactant is greater than or equal to 50 and less than or equal to 1040.

2. The polishing composition of 1. above, comprising a corrosion inhibitor.

3. The polishing composition of 1, or 2. above, wherein the abrasive has a particle size distribution defined by (D90−D10)/D50 of less than or equal to 0.60.

4. The polishing composition of any of 1. to 3. above, wherein the abrasive comprises particles having an aspect ratio of less than or equal to 1.1.

5. The polishing composition of any of 1. to 4. above, wherein the phosphate surfactant comprises a polyoxyethylene alkylphenyl ether phosphate or a polyoxyethylene alkenyl ether phosphate.

6. The polishing composition of any of 1. to 5. above, wherein the organic acid comprises a carboxy group and a hydroxy group.

7. The polishing composition of any of 1. to 6. above, wherein the EC controller comprises a salt of the organic acid.

8. The polishing composition of any of 1. to 7. above, wherein the water-soluble polymer comprises a polysaccharide.

9. The polishing composition of any of 1. to 8. above, further comprising an oxidizer.

10. The polishing composition of 9. above, wherein the oxidizer comprises hydrogen peroxide.

11. A method of polishing a substrate surface, wherein the substrate surface comprises two or more of Cu, Ta, SiCN, and TEOS, the method comprising: contacting the substrate surface with the polishing composition according to any of 1. to 10. above and a polishing pad; and moving the polishing pad against the substrate surface while the polishing composition is in contact with the substrate surface; wherein A2/A3 is 0.85 or greater.

12. The method of 11. above, wherein the polishing achieves a flatness of the substrate surface of less than or equal to 90, wherein the flatness is defined by (A3−A2)×(0.5×A1).

### Examples

### Example 1 Materials and Methods

### Preparation of Polishing Compositions

To investigate the effect of surfactant type and concentration on the polishing characteristics of polishing compositions according to the present disclosure, polishing compositions containing silica abrasives (see Table 1) were prepared and used to assess the removal rates of TEOS, as well as Ta and Cu films deposited on silicon wafers having a thermal oxide layer derived from TEOS, along with the flatness obtained on substrates having Ta and Cu lines separated by TEOS spacers.

Polishing compositions used in Examples described herein were prepared by adding deionized water, 0.1 wt. % benzotriazole (BTA) as the corrosion inhibitor, 0.2 wt. % of an EC controller, the phosphate surfactant (see Table 2), 0.018 wt. % pullulan as the water-soluble polymer, 0.1 wt. % citric acid as the organic acid, 1.0 wt. % of H₂O₂ (30 wt. % in water) as the oxidizer, and 5.2 wt. % silica abrasives (see Table 1), while mixing and finally adding deionized water to obtain the final weight. In Examples where pullulan was used, the weight-average molecular weight of the pullulan was 200,000. All weight percentages are reported as a percentage of the final weight. The pH of the composition was adjusted by monitoring the pH while adding potassium hydroxide and/or citric acid as the pH adjusting agent until the selected composition pH (e.g., 10) was reached.

TABLE 1
Abrasives Used in Polishing Compositions

| | | Surface | | | |
|---|---|---|---|---|---|
| Abrasive | MPS (nm) | Modifi- cation | K+ Conc. | Aspect Ratio | $\frac{( {D}_{90} - {D}_{10} )}{{D}_{50}}$ |
| 1 | 70 | Yes | < 1 ppm | 1.2 | 0.66 |
| 2 | 70 | No | < 1 ppm | 1.2 | 0.66 |
| 3 | 120 | No | < 1 ppm | 1.09 | 0.56 |
| 4 | 120 | Yes | < 1 ppm | 1.09 | 0.56 |
| 5 | 31 | No | < 1 ppm | 1.3 | 1.8 |
| 6 | 31 | Yes | < 1 ppm | 1.3 | 1.8 |
| 7 | 180 | No | < 1 ppm | 1.12 | 0.63 |

The abrasives 1 to 7 are those with high purity with low concentration of K⁺, which is a residual metal, as shown in Table 1 above. Note that values of the K⁺ concentration are those measured by elemental analysis using ICP.

### pH Measurement

The pH of polishing compositions according to the present disclosure was determined using a Thermo-Fisher Scientific VSTAR94 pH Meter.

Mean Particle Size/Size distribution Measurement

Mean particle sizes and size distributions for various abrasives in polishing compositions according to the present disclosure were determined using a ZETASIZER® (Malvern Panalytical).

### Removal Rate Measurement

To determine polishing removal rates, the polishing compositions were applied to the following substrates:

### For Removal Rate Measurement:

Ta: 2000 Å Ta on thermal oxide on Si substrate (Advantiv);
Cu: 10,000 Å epitaxial Cu on TiN on thermal oxide on silicon (Advantiv); and
TEOS: 10,000 Å TEOS on Si substrate (Advantiv)

### For Topography Correction Measurement:

Patterned wafer: MIT754mask (7000 Å Cu; 100 Å Ta; 3000 Å TEOS)
   Polishing Removal Rates were Determined Using the Following Polishing Conditions:
Polisher: 300 mm Polisher (Reflexion LK);
Polishing pad: Fujibo H8000;
Conditioner: 3M A82;
Downforce: 1.0 psi;
Platen rotation: 73 rpm;
Head rotation: 63 rpm;
Slurry flow rate: 200 mL/min.

To assess the removal rates achieved by the polishing compositions, film thickness before and after polishing was measured using a Resmap Resistivity Mapping System (Creative Design Engineering, Inc.) for Ta and Cu films, or a KLA ASET-F5X Pro Optical Thin Film Measurement System (KLA Corporation) for TEOS substrates.

### Topography Correction and Flatness Measurements

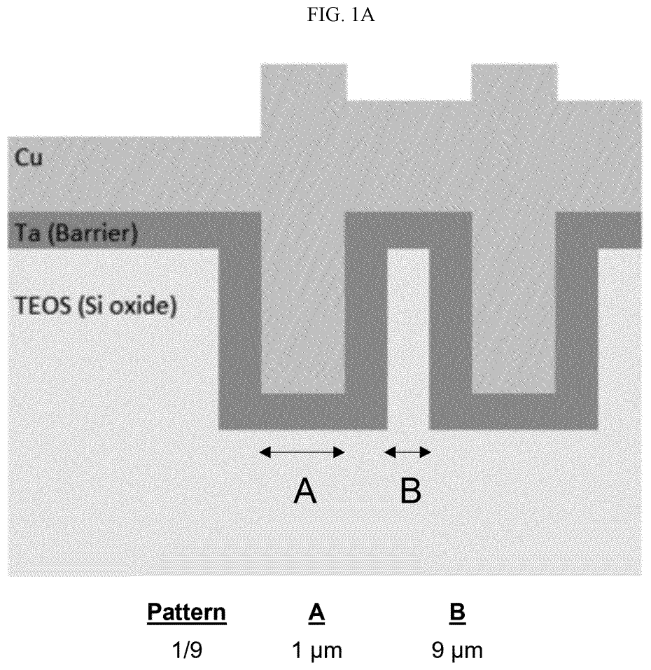

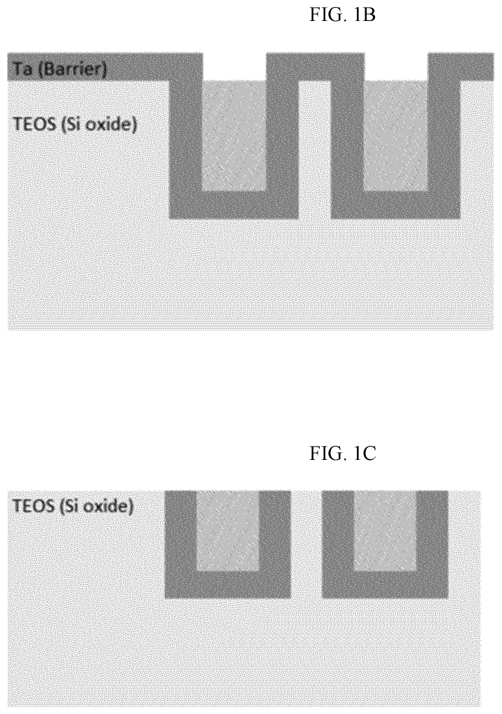

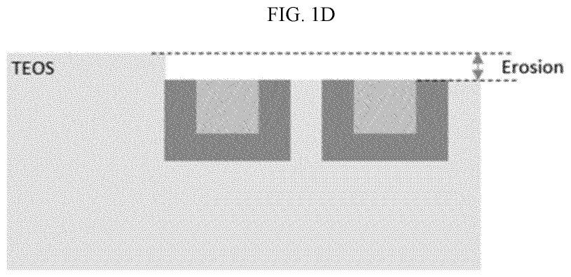

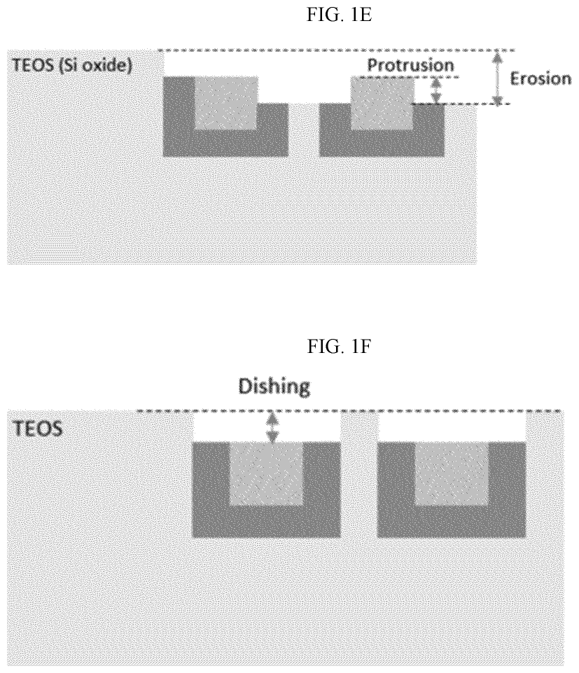

Referring to FIGS. 1A-1F, to assess topography correction, a patterned Si wafer with a 3000 Å thermal oxide (derived from TEOS) was patterned with trenches for depositing Cu lines. As shown in FIG. 1A, for a “1/9” pattern, the trench is 1 μm wide, while the inter-trench spacing is 9 μm. A Ta barrier layer (100 Å) was deposited across the patterned wafer, followed by a 7000 Å Cu layer. Referring to FIG. 1B, the Cu film was polished using a Cu polishing slurry, leaving behind a barrier layer and Cu lines within the trenches. The patterns tested in the Examples below (see Tables 2-4) were “1.5/0.5” patterns, with a 1.5-km-wide trench and an inter-trench spacing of 0.5 km.

The patterned wafers with Cu lines were then subjected to barrier layer polishing using polishing compositions according to the present disclosure, according to the conditions disclosed above. Referring to FIG. 1C, if the barrier layer polishing conditions have ideal Ta/TEOS and Cu/TEOS selectivity, the top of the TEOS layer on the non-patterned portion of the surface (“the TEOS reference level”) will be nearly level with the top of the Cu layer after barrier layer polishing. Referring to FIGS. 1D-1F, if the barrier layer polishing conditions have non-ideal Ta/TEOS and Cu/TEOS selectivity, there will be a height difference between the top of the TEOS layer on the non-patterned portion of the surface (“the TEOS reference level”) and the top of the Cu layer after barrier layer polishing. This will result in erosion, protrusions, and dishing.

In practice, a height difference typically exists after Cu polishing, and the barrier polishing compositions are assessed for topography correction (nm). Thus, referring to FIG. 1F, if the height difference between the TEOS reference level and the top of Cu layer after barrier layer polishing is less than the height difference before barrier layer polishing, the topography is said to have been corrected, and the topography correction (before (nm)—after (nm)) will reflect a positive value. Likewise, if the height difference between the TEOS reference level and the top of the Cu layer after barrier layer polishing is greater than the height difference before barrier layer polishing, the topography correction (before (nm)—after (nm)) will reflect a negative value. Accordingly, the “more positive” or “less negative” the topography correction (nm), the better a given polishing composition is able to correct (or avoid exacerbating) non-ideal topography. Meanwhile, the “less positive” or “more negative” the topography correction (nm), the less a given polishing composition is able to correct (or avoid exacerbating) non-ideal topography. For purposes of this disclosure, a positive topography value (nm) indicates the top of the Cu layer is below the TEOS reference level.

To assess topography correction, surface topography was measured using a Park Systems XE-120 AFM (Park Systems).

Referring to FIG. 2, to determine flatness, surface topography was measured using a Park Systems XE-120 AFM (Park Systems) to measure the width of the top of a TEOS feature (A2), the height of the top of a TEOS feature relative to the top of an adjacent Ta or Cu feature (A1). Given a width of the TEOS feature (A3) of about 500 nm, the flatness is calculated using Equation 2 below

$$Flatness = ( A 3 - A 2 ) \times ( 0.5 \times A 1 ) \qquad ( 2 )$$

### Example 2. Effect of Topography Controller (Surfactant) on Flatness of Polished Ta/Cu/TEOS Patterned Substrates

To assess the effect of surfactant type and concentration on polishing performance, the polishing compositions shown in Table 2 were prepared according to the procedure described in Example 1, and their removal rates for Ta, Cu, and TEOS, topography correction, and flatness were assessed according to the methods disclosed above in Example 1. Although the types and concentrations of phosphate surfactants were varied, all polishing compositions tested contained the following components at the following concentrations:
deionized water;
5.2 wt. % Abrasive 3 (see Table 1);
0.5 wt. % KOH;
0.1 wt. % citric acid;
0.1 wt. % BTA;
0.018 wt. % pullulan;
0.2 wt. % ammonium citrate dibasic;
1.0 wt. % H₂O₂ (30%).

As shown in Table 2, polishing compositions containing Abrasive 3 (unmodified colloidal silica, MPS=120 nm) and polyoxyethylene (7) nonylphenyl phosphate (e.g., Slurries 3, 4, and 5, at 0.01 wt. %, 0.05 wt. %, and 0.1 wt. %, respectively), polyoxyethylene (4) nonyl phenyl phosphate (Slurry 11), polyoxyethylene (10) nonyl phenyl phosphate (Slurry 12), and polyoxyethylene (10) oleyl ether phosphate (Slurry 8) showed excellent flatness performance (e.g., less than 10).

Further, slurries with surfactant concentrations of 0.01 wt. % to 0.1 wt. % (e.g., Slurries 3-5) showed significantly improved flatness performance when compared to slurries with surfactant concentrations of less than 0.01 wt. % (e.g., Slurries 1-2).

### Example 3. Effect of Abrasive Type on Polishing Performance on Ta/Cu/TEOS Patterned Substrates

To assess the effect of abrasive type and size on polishing performance, the polishing compositions shown in Table 3 were prepared according to the procedure described in Example 1, and their removal rates for Ta, Cu, and TEOS, topography correction, and flatness were assessed according to the methods disclosed above in Example 1. Although the types and sizes of abrasives were varied, all polishing compositions tested contained the following components at the following concentrations:
deionized water;
5.2 wt. % Abrasive 1-7 (see Table 1);
0.5 wt. % KOH;
0.1 wt. % citric acid;
0.1 wt. % BTA;
0.018 wt. % pullulan;
0.2 wt. % ammonium citrate dibasic;
1.0 wt. % H₂O₂ (30%); and
0.01 wt. % polyoxyethylene (7) nonylphenyl phosphate.

As shown in Table 3, polishing compositions containing abrasive having MPS of 120 nm (Abrasive 3 and Abrasive 4; slurries 3 and 15) showed the best flatness performance (8, 10), along with Cu, Ta, and TEOS removal rates at least on par with compositions containing the other abrasive types and the best topography correction performance among abrasives studied.

### Example 4. Effect of EC Controller Type on Polishing Performance on Ta/Cu/TEOS Patterned Substrates

To assess the effect of EC controller (salt) type on polishing performance, the polishing compositions shown in Table 4 were prepared according to the procedure described in Example 1, and their removal rates for Ta, Cu, and TEOS, topography correction, and flatness were assessed according to the methods disclosed above in Example 1. Although the type of EC controller was varied, all polishing compositions tested contained the following components at the following concentrations:
deionized water;
5.2 wt. % Abrasive 3 (see Table 1);
0.05 wt. % POE (7)-nonylphenylphosphate;
0.5 wt. % KOH;
0.1 wt. % citric acid;
0.1 wt. % BTA;
0.018 wt. % pullulan;
0.2 wt. % of EC Controller (Table 4); and
1.0 wt. % H₂O₂ (30%).

TABLE 2
Effect of Surfactant Type and Concentration on Polishing Performance

| | | | | Removal | | | 1.5 μm/ | | | | | |
|---|---|---|---|---|---|---|---|---|---|---|---|---|
| | Surfactant | | | Rate | | | 0.5 μm | | Topography | | | |
| | | Conc.(wt | Abrasive/ | (nm/min) | | | (nm) | | Correction | A1 | A2 | |
| Slurry | Type | %) | Surfactant | Ta | Cu | TEOS | Pre | Post | (nm) | (nm) | (nm) | Flatness |
| 1 | POE (7)- | 0 | — | 55 | 35 | 36 | 45 | 15.2 | 29.8 | 5.1 | 300 | 510 |
| | nonylphenylphosphate | | | | | | | | | | | |
| 2 | POE (7)- | 0.005 | 1040 | 56 | 34 | 36 | 45 | 3.1 | 41.9 | 2.1 | 320 | 189 |
| | nonylphenylphosphate | | | | | | | | | | | |
| 3 | POE (7)- | 0.01 | 520 | 56 | 34 | 36 | 45 | 0.1 | 44.9 | 0.5 | 470 | 8 |
| | nonylphenylphosphate | | | | | | | | | | | |
| 4 | POE (7)- | 0.05 | 104 | 56 | 33 | 36 | 45 | −3.5 | 48.5 | 0.2 | 485 | 2 |
| | nonylphenylphosphate | | | | | | | | | | | |
| 5 | POE (7)- | 0.1 | 52 | 55 | 33 | 36 | 45 | −6.5 | 51.5 | 0.3 | 480 | 3 |
| | nonylphenylphosphate | | | | | | | | | | | |
| 8 | POE (10) oleyl | 0.01 | 520 | 55 | 33 | 35 | 45 | 0.3 | 44.7 | 0.4 | 479 | 4 |
| | ether phosphate | | | | | | | | | | | |
| 9 | dodecylbenzene | 0.01 | 520 | 51 | 30 | 33 | 45 | 8.4 | 36.6 | 2.4 | 388 | 134 |
| | sulfonic acid | | | | | | | | | | | |
| 10 | lauric acid | 0.01 | 520 | 52 | 32 | 32 | 45 | 7.8 | 37.2 | 2.6 | 401 | 129 |
| 11 | POE (4)- | 0.01 | 520 | 54 | 33 | 36 | 45 | 0.2 | 44.8 | 0.5 | 468 | 8 |
| | nonylphenylphosphate | | | | | | | | | | | |
| 12 | POE (10)- | 0.01 | 520 | 56 | 34 | 36 | 45 | 0.2 | 44.8 | 0.5 | 464 | 9 |
| | nonylphenylphosphate | | | | | | | | | | | |

Note that the pH of all the slurries (Slurries 1 to 5, and 8 to 22) was adjusted to 10.0.

As shown in Table 4, polishing compositions containing ammonium citrate dibasic (slurry 4), wherein the anion is the same as the anion present in the organic acid (i.e., citric acid), achieved significantly flatter surfaces than polishing compositions containing different EC controllers containing an anion different from the anion present in the organic acid (slurries 19-22).

TABLE 3
Effect of Abrasive Type on Polishing Performance

| | | | | | | | 1.5 | | | | | |
|---|---|---|---|---|---|---|---|---|---|---|---|---|
| | | | | | | | μm/0.5 | | | | | |
| | | | | Removal Rate | | | μm | | Topo- | | | |
| | | | | (nm/) | | | (nm) | | graphy | | | |
| Slurry | Abrasive Type | MPS (nm) | $\frac{( {D}_{90} - {D}_{10} )}{{D}_{50}}$ | Ta | Cu | TEOS | Pre | Post | Correction (nm) | A1 (nm) | A2 (nm) | Flatness |
| 14 | Abrasive | 70 | 0.66 | 58 | 36 | 35 | 45 | 18.2 | 26.8 | 7.6 | 236 | 1003 |
| | 1 | | | | | | | | | | | |
| 13 | Abrasive | 70 | 0.66 | 58 | 35 | 34 | 45 | 18.4 | 26.6 | 7.2 | 234 | 958 |
| | 2 | | | | | | | | | | | |
| 3 | Abrasive | 120 | 0.56 | 56 | 34 | 36 | 45 | 3.1 | 41.9 | 0.5 | 470 | 8 |
| | 3 | | | | | | | | | | | |
| 15 | Abrasive | 120 | 0.56 | 56 | 34 | 36 | 45 | 0.3 | 44.7 | 0.5 | 460 | 10 |
| | 4 | | | | | | | | | | | |
| 16 | Abrasive | 31 | 1.8 | 36 | 21 | 13 | 45 | 29 | 16 | 9.8 | 221 | 1367 |
| | 6 | | | | | | | | | | | |
| 17 | Abrasive | 31 | 1.8 | 36 | 21 | 12 | 45 | 33 | 12 | 8.9 | 218 | 1255 |
| | 5 | | | | | | | | | | | |
| 18 | Abrasive | 180 | 0.63 | 59 | 37 | 38 | 45 | 31.3 | 13.7 | 9.8 | 371 | 632 |
| | 7 | | | | | | | | | | | |

TABLE 4
Effect of EC Controller Type on Polishing Performance

| | | Removal | | | 1.5 μm/ | | | | | |
|---|---|---|---|---|---|---|---|---|---|---|
| | | Rate | | | 0.5 μm | | Topography | | | |
| | | (nm/min) | | | (nm) | | Correction | A1 | A2 | |
| Slurry | EC Controller | Ta | Cu | TEOS | Pre | Post | (nm) | (nm) | (nm) | Flatness |
| 4 | ammonium | 56 | 33 | 36 | 45 | −3.5 | 48.5 | 0.2 | 485 | 2 |
| | citrate | | | | | | | | | |
| | (dibasic) | | | | | | | | | |
| 19 | potassium | 53 | 25 | 32 | 45 | 10 | 35 | 1.3 | 399 | 66 |
| | carbonate | | | | | | | | | |
| 20 | ammonium | 51 | 46 | 31 | 45 | −7.2 | 52.2 | 1.4 | 381 | 83 |
| | sulfate | | | | | | | | | |
| 21 | ammonium | 57 | 48 | 32 | 45 | −7.4 | 52.4 | 1.3 | 377 | 80 |
| | acetate | | | | | | | | | |
| 22 | ammonium | 56 | 47 | 32 | 45 | −6.8 | 51.8 | 1.3 | 364 | 88 |
| | phosphate | | | | | | | | | |

While certain embodiments have been illustrated and described, it should be understood that changes and modifications may be made therein in accordance with ordinary skill in the art without departing from the technology in its broader aspects as defined in the following claims.

The compositions and methods illustratively described herein may suitably be practiced in the absence of any element or elements, limitation or limitations, not specifically disclosed herein. Thus, for example, the terms “containing”, “including,” containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof. It is recognized that various modifications are possible within the scope of the disclosure claimed. Thus, it should be understood that although the present disclosure has been specifically disclosed by preferred embodiments and optional features, modification and variation of the disclosure embodied therein herein disclosed may be resorted to by those skilled in the art, and that such modifications and variations are considered to be within the scope of this disclosure.

The disclosure has been described broadly and generically herein. Each of the narrower species and subgeneric groupings falling within the generic disclosure also form part of the methods. This includes the generic description of the methods with a proviso or negative limitation removing any subject matter from the genus, regardless of whether or not the excised material is specifically recited herein. The present technology is not to be limited in terms of the particular embodiments described in this application, which are intended as single illustrations of individual aspects of the present technology. Many modifications and variations of this present technology can be made without departing from its spirit and scope, as will be apparent to those skilled in the art. Functionally equivalent methods and apparatuses within the scope of the present technology, in addition to those enumerated herein, will be apparent to those skilled in the art from the foregoing descriptions. Such modifications and variations are intended to fall within the scope of the present technology. It is to be understood that this present technology is not limited to particular methods, reagents, compounds compositions or biological systems, which can, of course, vary. It is also to be understood that the terminology used herein is for the purpose of describing particular embodiments only, and is not intended to be limiting.

One skilled in the art readily appreciates that the present disclosure is well adapted to carry out the objects and obtain the ends and advantages mentioned, as well as those inherent therein. Modifications therein and other uses will occur to those skilled in the art. These modifications are encompassed within the spirit of the disclosure and are defined by the scope of the claims, which set forth non-limiting embodiments of the disclosure.

In addition, where features or aspects of the disclosure are described in terms of Markush groups, those skilled in the art will recognize that the disclosure is also thereby described in terms of any individual member or subgroup of members of the Markush group.

All references, articles, publications, patents, patent publications, and patent applications cited herein are incorporated by reference in their entireties for all purposes. However, mention of any reference, article, publication, patent, patent publication, and patent application cited herein is not, and should not be taken as, an acknowledgment or any form of suggestion that they constitute valid prior art or form part of the common general knowledge in any country in the world.

The present application is based on U.S. Provisional Patent Application No. 63/698,658 filed on Sep. 25, 2024, the content of which is incorporated herein by reference in its entirety.

Other embodiments are set forth in the following claims.

What is claimed is:

1. A polishing composition, comprising:
an abrasive, wherein the abrasive has a mean particle size (MPS) of 100 nm to 150 nm;
a phosphate surfactant;
an electronic conductivity (EC) controller;
an organic acid; and
a water-soluble polymer,
wherein a ratio of a concentration of the abrasive to a concentration of the phosphate surfactant is greater than or equal to 50 and less than or equal to 1040.

2. The polishing composition of claim 1, comprising a corrosion inhibitor.

3. The polishing composition of claim 1, wherein the abrasive has a particle size distribution defined by (D90−D10)/D50 of less than or equal to 0.60.

4. The polishing composition of claim 1, wherein the abrasive comprises particles having an aspect ratio of less than or equal to 1.1.

5. The polishing composition of claim 1, wherein the phosphate surfactant comprises a polyoxyethylene alkylphenyl ether phosphate or a polyoxyethylene alkenyl ether phosphate.

6. The polishing composition of claim 1, wherein the organic acid comprises a carboxy group and a hydroxy group.

7. The polishing composition of claim 1, wherein the EC controller comprises a salt of the organic acid.

8. The polishing composition of claim 1, wherein the water-soluble polymer comprises a polysaccharide.

9. The polishing composition of claim 1, further comprising an oxidizer.

10. The polishing composition of claim 9, wherein the oxidizer comprises hydrogen peroxide.

11. A method of polishing a substrate surface, wherein the substrate surface comprises two or more of Cu, Ta, SiCN, and TEOS, the method comprising:
contacting the substrate surface with the polishing composition of claim 1 and a polishing pad; and
moving the polishing pad against the substrate surface while the polishing composition is in contact with the substrate surface;
wherein A2/A3 is 0.85 or greater.

12. The method of claim 11, wherein the polishing achieves a flatness of the substrate surface of less than or equal to 90, wherein the flatness is defined by (A3−A2)×(0.5×A1).
